(19) United States
(12) Patent Application Publication
(10) Pub. No.: US 2024/0381528 A1
(43) Pub. Date: Nov. 14, 2024

(54) FLEXIBLE LAMINATE MATERIAL

(71) Applicant: THE CHEMOURS COMPANY FC, LLC, WILMINGTON, DE (US)

(72) Inventors: RONG LIAO, SHANGHAI (CN); BRIAN DAVID AMOS, WORCESTER, MA (US); JOHN C. FRANKOSKY, LANDENBERG, PA (US); FRANCISCUS CORNELIS JOANNES HULSEBOSCH, CESAY (FR); SCOTT DAVID KENNEDY, NEWARK, DE (US); YING WANG, NEW CASTLE, DE (US); ROBERT THOMAS YOUNG, NEW CASTLE, DE (US); LIU XIAOLIN, LANDENBERG, PA (US)

(73) Assignee: THE CHEMOURS COMPANY FC, LLC, WILMINGTON, DE (US)

(21) Appl. No.: 18/293,208

(22) PCT Filed: May 5, 2022
(86) PCT No.: PCT/CN2022/090911

§ 371 Date: Jan. 29, 2024

(30) Foreign Application Priority Data
Jul. 30, 2021 (WO) PCT/CN2021/109685
May 5, 2022 (WO) PCT/CN2022/090911

(51) Int. Cl. H05K 1/03; H01Q 1/38; H05K 1/02; H05K 3/46

(52) U.S. Cl. CPC H05K 1/036; H01Q 1/38; H05K 1/024; H05K 1/0298; H05K 3/4635

(57) ABSTRACT

A laminate article includes a dielectric substrate including a perfluorocopolymer matrix comprising a fluorinated perfluorocopolymer and a non fluorinated perfluorocopolymer; a quartz fabric embedded in the perfluorocopolymer matrix; and an additive material dispersed in the perfluorocopolymer matrix, in which the additive material is capable of absorbing ultraviolet light; and a conductive cladding disposed on a surface of the dielectric substrate.

### CROSS REFERENCE TO RELATED APPLICATIONS

This application claims the benefit of priority to PCT Application Serial No.: PCT/CN2022/090911, filed May 19, 2022 and PCT Application Serial No. PCT/CN2021/109685, filed on Jul. 30, 2021, the contents of which are incorporated here by reference in their entirety.

### BACKGROUND

Metal-clad laminates are used as printed-wiring board substrates in various electronics applications.

### SUMMARY

In a first aspect, a laminate article includes a dielectric substrate including a perfluorocopolymer matrix including a fluorinated perfluorocopolymer and a non-fluorinated perfluorocopolymer; a quartz fabric embedded in the perfluorocopolymer matrix; and an additive material dispersed in the perfluorocopolymer matrix, in which the additive material is capable of absorbing ultraviolet light; and a conductive cladding disposed on a surface of the dielectric substrate.

Embodiments can include one or any combination of two or more of the following features.

The laminate article has a thickness of between 20 μm and 200 μm, e.g., between 30 μm and 90 μm, e.g., between 30 μm and 60 μm.

The dielectric substrate has a dielectric constant at 10 GHz of between 2.10 and 2.50, e.g., between 2.10 and 2.30.

The dielectric substrate has a thermal coefficient of dielectric constant with a value of between −250 to +50 ppm/° C. over a temperature range of 0 to 100° C.

The dielectric substrate has a dissipation factor at 10 GHz of less than 0.001, e.g., between 0.0006 and 0.001, e.g., between 0.0006 and 0.0008.

The laminate article has a planar shape defining an X-Y plane, and in which a coefficient of thermal expansion of the laminate article in the X-Y plane is between 5 and 25 ppm/° C., e.g., between 14 and 20 ppm/° C., e.g., between 16 and 22 ppm/° C.

The fluorinated perfluorocopolymer includes a fluorinated tetrafluoroethylene/perfluoro(alkyl vinyl ether) copolymer and in which the non-fluorinated perfluorocopolymer includes a non-fluorinated tetrafluoroethylene/perfluoro(alkyl vinyl ether) copolymer.

The perfluorocopolymer matrix includes between 50 and 90 weight percent of the fluorinated perfluorocopolymer, e.g., between 50 and 80 weight percent of the perfluorocopolymer. The perfluorocopolymer matrix comprises between 10 and 50 weight percent of the non-fluorinated perfluorocopolymer.

A number of carboxyl end groups per million carbon atoms in the perfluorocopolymer matrix is sufficient for the laminate article to form no conductive anodic filaments (CAF).

A number of carboxyl end groups per million carbon atoms in the perfluorocopolymer matrix provides the laminate article with a peel strength between the dielectric substrate and the conductive cladding of greater than 2 lb./inch.

The number of carboxyl end groups per million carbon atoms in the perfluorocopolymer matrix is between 30 and 70.

The fluorinated perfluorocopolymer has 5 or fewer carboxyl end groups per million carbon atoms.

The non-fluorinated perfluorocopolymer has between 100 and 300 carboxyl end groups per million carbon atoms.

The perfluorocopolymer matrix has a melt flow rate (MFR) of between 10 g/10 minutes and 30 g/10 minutes.

The perfluorocopolymer matrix has a solder float resistance of at least 10 seconds, e.g., 60 seconds, at 288° C.

The quartz fabric has a basis weight of less than 50 g/m2, e.g., less than 25 g/m2.

The quartz fabric has a thickness between 10 μm and 30 μm.

The quartz fabric includes an aminosilane or methacrylate silane surface chemistry treatment.

The quartz fabric includes a plasma-treated or corona-treated quartz fabric.

The quartz fabric is impregnated with a fluoropolymer.

The quartz fabric includes a fluoropolymer coating.

The quartz fabric is pretreated with a fluoropolymer treatment prior to incorporation into the laminate article.

The dielectric substrate includes between 5 and 20 volume percent of the quartz fabric and between 80 and 95 volume percent of the perfluorocopolymer matrix.

A water contact angle of the quartz fabric is between 0° and 60°.

The additive material includes inorganic particles. For instance, the inorganic particles include particles of cerium oxide, titanium dioxide, silicon dioxide, barium titanate, calcium titanate, or zinc oxide.

The additive material includes a thermoset polymer.

The additive material is present in the perfluorocopolymer matrix at a volume percent of less than 2%.

The additive material is dispersed homogeneously throughout the perfluorocopolymer matrix.

The conductive cladding is disposed on two opposing surfaces of the dielectric substrate.

The conductive cladding includes a copper foil, e.g., disposed on the surface of the dielectric substrate by a lamination process.

The conductive cladding has a thickness of less than 72 μm, e.g., between 5 m and 18 μm.

The conductive cladding has a root mean square (RMS) roughness of less than 1 μm, e.g., less than 0.5 μm.

In a second aspect, a printed-wiring board includes the laminate article of the first aspect, in which a conductor pattern is formed in the conductive cladding.

In some examples, a through-hole is defined through a thickness of the laminate article; and including a copper film plating the through-hole.

In a third aspect, a multilayer printed-wiring board includes a multilayer laminated structure including multiple printed-wiring boards according to the second aspect.

Embodiments can include one or any combination of two or more of the following features.

The multilayer printed-wiring board includes a thermoplastic adhesive disposed between adjacent printed-wiring boards in the laminated structure.

The thermoplastic adhesive was bonded at a temperature between 0 and 200° C. below a melting point of the perfluorocopolymer matrix, e.g., at a temperature between 0 and 50° C. below the melting point of the perfluorocopolymer matrix.

The multilayer printed-wiring board includes a thermoset adhesive disposed between adjacent printed-wiring boards in the laminated structure.

The thermoset adhesive was cured at a temperature of between 150° C. and 250° C.

A through-hole is defined through at least a portion of the thickness of the multilayer printed-wiring board; and including a copper film plating the through-hole.

In a fourth aspect, an antenna usable with a 5G communications network includes a printed-wiring board according to the second or third aspect.

In a fifth aspect, a method of making a multilayer printed-wiring board includes forming a conductor pattern in the conductive cladding of each of multiple of the laminate articles of the first aspect to form respective printed-wiring boards; and laminating the multiple printed-wiring boards to form a multilayer laminated structure.

Embodiments can include one or any combination of two or more of the following features.

Laminating the multiple printed-wiring boards includes adhering adjacent printed-wiring boards using a thermoplastic adhesive.

The method includes bonding the thermoplastic adhesive at a temperature between 0° C. and 200° C. below a melting point of the perfluorocopolymer matrix, e.g., at a temperature between 0° C. and 50° C. below the melting point of the perfluorocopolymer matrix.

Laminating the multiple printed-wiring boards includes adhering adjacent printed-wiring boards using a thermoset adhesive.

The method includes curing the thermoset adhesive at a temperature of between 150° C. and 250° C.

The method includes defining a through-hole through at least a portion of the thickness of the multilayer laminated structure., e.g., in an ultraviolet drilling process.

In a sixth aspect, a method of making a laminate article includes forming a layered article. The layered article includes first and second polymer films, each film including: a perfluorocopolymer matrix including a fluorinated perfluorocopolymer and a non-fluorinated perfluorocopolymer, and an ultraviolet additive, a quartz fabric disposed between the first and second polymer films; and a conductive cladding disposed in contact with the first film. The method includes applying heat and pressure to the layered article to form the laminate article.

Embodiments can include one or any combination of two or more of the following features.

The fluorinated perfluorocopolymer includes a fluorinated tetrafluoroethylene/perfluoro(alkyl vinyl ether) copolymer and the non-fluorinated perfluorocopolymer includes a non-fluorinated tetrafluoroethylene/perfluoro(alkyl vinyl ether) copolymer.

Applying heat and pressure to the layered article includes compressing the layered article in a heated platen.

Applying heat and pressure to the layered article includes processing the layered article in a roll-to-roll lamination process.

Applying heat and pressure to the layered article includes applying to the layered article a temperature between 1° and 30° C. greater than a melting point of the perfluorocopolymer matrix.

Applying heat and pressure to the layered article includes applying to the layered article a temperature of between 300° C. and 400° C.

Applying heat and pressure to the layered article includes applying to the layered article a pressure of between 200 psi and 1000 psi.

The method includes forming the first and second films in a melt processing and extrusion process.

Forming the first and second films includes mixing the fluorinated perfluorocopolymer and the non-fluorinated perfluorocopolymer.

The method includes dispersing the additive material in the fluorinated perfluorocopolymer prior to mixing the fluorinated perfluorocopolymer and the non-fluorinated perfluorocopolymer.

The method includes treating the quartz fabric with a fluoropolymer treatment.

Treating the quartz fabric with a fluoropolymer treatment includes coating the quartz fabric with a fluoropolymer coating.

Coating the quartz fabric with a fluoropolymer coating includes coating the quartz fabric in a solution coating process.

Coating the quartz fabric with a fluoropolymer coating includes depositing fluoropolymer particles on a surface of the quartz fabric.

Each polymer film includes a first layer including the fluorinated perfluorocopolymer and the non-fluorinated perfluorocopolymer and a second layer including the non-fluorinated perfluorocopolymer, and in which each second layer is disposed in contact with the quartz fabric and each second layer is disposed in contact with the conductive cladding.

The details of one or more implementations are set forth in the accompanying drawings and the description below. Other features and advantages will be apparent from the description and drawings, and from the claims.

### BRIEF DESCRIPTION OF DRAWINGS

FIG. 1 is a diagram of a flexible, metal-clad laminate.

FIG. 2 is a diagram of a layered structure for a flexible, metal-clad laminate.

FIGS. 3A and 3B are diagrams of laminates with conductive anodic filaments.

FIGS. 4 and 5 are diagrams of printed-wiring boards.

FIG. 6 is a diagram of a communications network.

FIG. 7 is a diagram of a roll-to-roll lamination process.

FIG. 8 is a flow chart of a method of making a flexible, metal-clad laminate.

FIG. 9 is a plot of the dielectric constant at 5 GHz for various flexible copper clad laminates.

FIG. 10 is a plot of the dissipation factor at 5 GHz for various flexible copper clad laminates.

FIG. 11 is a plot of peel strength test results for various flexible copper clad laminates.

FIG. 12 is a plot of wicking test results for various flexible copper-clad laminates.

FIG. 13 is a plot of the coefficient of thermal expansion for various flexible copper clad laminates.

FIG. 14 is a plot of the dielectric constant at 5 GHz for various flexible copper clad laminates.

FIG. 15 is a plot of the dissipation factor at 5 GHz for various flexible copper clad laminates.

FIG. 16 is a plot of thickness test results for various flexible copper clad laminates.

FIG. 17 is a plot of peel strength test results for various flexible copper clad laminates.

FIG. 18 is a plot of wicking test results for various flexible copper clad laminates.

FIG. 19 is a plot of the dielectric constant at 5 GHz for various flexible copper clad laminates.

FIG. 20 is a plot of the dissipation factor at 5 GHz for various flexible copper clad laminates.

FIG. 21 is a plot of thickness test results for various flexible copper clad laminates.

FIG. 22 is a plot of peel strength test results for various flexible copper clad laminates.

FIG. 23 is a plot of wicking test results for various flexible copper clad laminates.

FIG. 24 is a plot of peel strength test results for various flexible copper clad laminates.

FIG. 25 is a plot of wicking test results for various flexible copper clad laminates.

FIGS. 26 and 27 are plots of water contact angle measurements.

FIG. 28 is a plot of peel strength test results for various flexible copper clad laminates.

FIG. 29 is a plot of wicking test results for various flexible copper clad laminates.

FIGS. 30A and 30B are plots of modeled insertion losses.

FIGS. 31A and 31B are surface roughness scan results for two copper foils.

FIG. 32 is a plot of dissipation factor of blended PFA films as a function of the number of carboxyl end groups per 10⁶ carbon atoms in the films.

FIG. 33 is a plot of dissipation factor of a laminate as a function the number of carboxyl end groups per 10⁶ carbon atoms in blended PFA films.

FIG. 34 is a plot of sharpie wicking behavior of a laminate as a function the number of carboxyl end groups per 10⁶ carbon atoms in blended PFA films.

FIG. 35 is a plot of copper peel strength of a laminate as a function the number of carboxyl end groups per 10⁶ carbon atoms in blended PFA films.

### DETAILED DESCRIPTION

We describe here a metal-clad, flexible laminate with a low dielectric constant and low dissipation at high frequencies, e.g., at 10 GHz. The flexible laminates described here can be used for substrates for printed-wiring boards in high-frequency applications, such as for antennas for use in 5G cellular communications networks or for use with automotive radar, among other applications. The flexible laminates described here include a dielectric substrate formed of a perfluorocopolymer matrix with a quartz fabric, e.g., a woven quartz fabric, embedded therein. The perfluorocopolymer matrix includes a fully fluorinated perfluorocopolymer (referred to here as a “fluorinated perfluorocopolymer”) and a not fully fluorinated perfluorocopolymer (referred to here as a “non-fluorinated perfluorocopolymer”), such as fully fluorinated and not fully fluorinated tetrafluoroethylene/perfluoro(alkyl vinyl ether) copolymers. An additive material in the dielectric substrate is capable of absorbing ultraviolet light such that the laminate can be drilled with an ultraviolet laser, e.g., for formation of through-holes through the thickness of the laminate. The flexible laminate is clad on one or both sides by a conductive cladding, such as a copper foil.

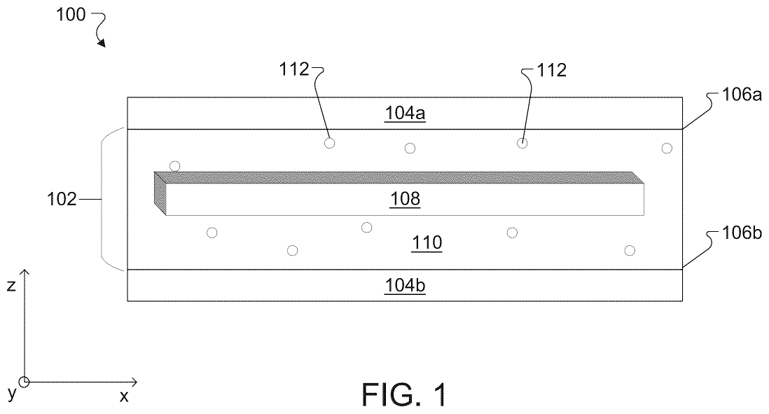

Referring to FIG. 1, a metal-clad, flexible laminate 100 includes a dielectric substrate 102 and a conductive cladding, such as a metal (e.g., copper) foil 104a, 104b (referred to collectively as the conductive cladding 104) disposed on top and bottom surfaces 106a, 106b, respectively, of the dielectric substrate 102. Although the conductive cladding 104 is present on both surfaces 106a, 106b of the dielectric substrate 102 in FIG. 1, in some examples, a conductive cladding is disposed on only a single surface (e.g., only the top surface 106a) of the dielectric substrate 102.

The dielectric substrate 102 of the flexible laminate 100 includes a quartz fabric 108, such as a woven quartz fabric, embedded in a perfluorocopolymer matrix 110 that includes a fluorinated perfluorocopolymer and a non-fluorinated perfluorocopolymer, such as fluorinated and non-fluorinated tetrafluoroethylene/perfluoro(alkyl vinyl ether) copolymers. As discussed further below, the perfluorocopolymer matrix 110 provides the dielectric substrate 102 with a low dielectric constant and low dissipation factor, while the quartz fabric enables the coefficient of thermal expansion (CTE) in the x-y plane of the dielectric substrate 102 to match the CTE of the conductive cladding 104. An additive material 112 that is capable of absorbing ultraviolet (UV) light, e.g., light having a wavelength of between 180 nm and 400 nm, is dispersed in the perfluorocopolymer matrix 110. The presence of the UV-responsive additive material 112 enables the flexible laminate 100 to be drilled by a UV laser, e.g., for formation of circuit structures such as vias through the thickness of the flexible laminate 100.

The flexible laminate 100 is a planar structure that has a thickness along the z-axis of less than about 200 μm or less than about 100 μm, e.g., between 20 μm and 200 m, e.g., between 30 μm and 90 μm or between 30 μm and 60 μm. The thickness of the dielectric substrate 102 constitutes most of the thickness of the flexible laminate 100. For instance, the dielectric substrate 102 has a thickness along the z-axis of less than about 200 μm or less than about 100 μm, e.g., between 20 μm and 200 μm, e.g., between 30 μm and 90 μm or between 30 μm and 60 μm. Each conductive cladding 104a, 104b has a thickness along the z-axis of less than about 72 μm, e.g., less than about 18 μm, e.g., between 5 μm and 18 μm.

The dielectric substrate 102 of the flexible laminate 100 has a low dielectric constant, e.g., a dielectric constant at 10 GHz of less than about 2.5, e.g., between 2.1 and 2.5, e.g., between 2.1 and 2.3. The dielectric constant has a thermal coefficient with aa value of between −250 and 50 ppm/° C., e.g., between −100 and 50 ppm/° C. or between −50 and 25 ppm/° C., over a temperature range of 0 to 100° C. The dielectric substrate 102 also has a low dissipation factor, e.g., a dissipation factor at 10 GHz of less than 0.0015, such as less than 0.001 or less than 0.0008, e.g., between 0.0002 and 0.001, e.g., between 0.0006 and 0.001, e.g., between 0.0006 and 0.0008.

The improved electrical properties (e.g., low dielectric constant and low dissipation factor) of the flexible laminate 100 make it possible for designers to realize improvements in insertion loss, e.g., of up to 25% or more for a given characteristic impedance versus incumbent flexible materials. It is believed that low levels of ferromagnetic elements (e.g., Fe, Ni, or Co) in the conductive cladding 104 (e.g., in the copper foil) can help achieve low insertion loss.

The coefficient of thermal expansion (CTE) of the dielectric substrate 102 and the CTE of the conductive cladding 104 are similar in the x-y plane of the flexible laminate 100. For instance, when the conductive cladding 104 is a copper foil, the CTE of the in the x-y plane of the dielectric substrate 102 can be between 5 and 25 ppm/° C., e.g., between 16 and 22 ppm/° C., e.g., between 14 and 20 ppm/° C. The matching of CTE values between the dielectric substrate 102 and the conductive cladding 104 provides the flexible laminate 100 with dimensional stability, e.g., a dimensional stability of less than about 0.1%, e.g., such that the flexible laminate maintains its original dimensions within about 0.1% when subjected to removal of the conductive cladding and a change in temperature.

The conductive cladding 104 of the flexible laminate 100 is adhered strongly to the dielectric substrate. For instance, a peel strength between the dielectric substrate 102 and the conductive cladding 104 is greater than 2 lb./inch, e.g., greater than 4 lb./inch, e.g., between 2 and 20 lb./inch or between 4 and 20 lb./inch. The flexible laminate 100 is mechanically robust against bending and can be flexed over bend radii typically found in electronic devices without failure of any of the components of the flexible laminate 100. This flexibility facilitates installation of the flexible laminate 100 into devices.

The flexible laminate 100 can be drilled by a UV laser and is compatible with metallization techniques, e.g., plasma metallization, such that through-holes can be formed through the thickness of the flexible laminate 100 (e.g., along the z-axis of the flexible laminate 100). The dielectric substrate 102 of the flexible laminate 100 has a solder float resistance at 288° C. of at least 5 seconds, at least 10 seconds, at least 30 seconds, or at least 60 seconds, e.g., between 5 and 20 seconds, between 10 and 15 seconds, between 10 and 30 seconds, between 10 and 60 seconds, or between 30 and 60 seconds.

The flexible laminate 100 can be used for a printed-wiring board, e.g., for flexible printed circuit board antennas. For instance, the dimensions and electrical properties of the flexible laminate 100 can make the flexible laminate 100 suitable for use in high-frequency applications, such as for antennas for mobile devices usable on 5G communications networks, as discussed further below, or for use with automotive radar or other high-frequency applications. In some examples, multiple flexible laminates 100 can themselves be laminated into a multilayer circuit board structure. The flexible laminate is substantially void-free and resistant to formation of conductive anodic filaments, which contributes to electrical reliability of the flexible laminate as printed-wiring board substrate.

The low dielectric constant and low dissipation factor of the dielectric substrate 102 of the flexible laminate 100 are due, at least in part, to the composition of the perfluorocopolymer matrix 110. The perfluorocopolymer matrix 110 includes a fluorinated perfluorocopolymer, such as a fluorinated tetrafluoroethylene/perfluoro(alkyl vinyl ether) copolymer; and a non-fluorinated perfluorocopolymer, such as a non-fluorinated tetrafluoroethylene/perfluoro(alkyl vinyl ether) copolymer. The fluorinated perfluorocopolymer, the non-fluorinated perfluorocopolymer, or both can be straight-chain, unbranched polymers. The fluorinated perfluorocopolymer has a low or zero polarity, and thus has a low dielectric constant and a low dissipation factor. However, fluorinated perfluorocopolymers are generally non-reactive, e.g., the fluorinated copolymer has poor adhesion to the quartz fabric 108 and the conductive cladding 104. The non-fluorinated perfluorocopolymer has reactive end groups (e.g., carboxyl or amide end groups) that are attracted to the quartz fabric 108 and the conductive cladding 104. The presence of these reactive end groups promotes adhesion between the perfluorocopolymer matrix and the quartz fabric 108 and the conductive cladding 104.

In some examples, the perfluorocopolymers are made by aqueous dispersion polymerization, and as-polymerized can contain at least about 400 reactive end groups per 10⁶ carbon atoms. Most of these end groups are thermally unstable in the sense that when exposed to heat, such as encountered during extrusion and film formation, or film lamination conditions, they can undergo chemical reaction such as decomposition and decarboxylation, either discoloring the extruded polymer or filling it with non-uniform bubbles or both. To make the fluorinated perfluorocopolymers described here, polymerized perfluorocopolymer is stabilized to replace substantially all of the reactive end groups by thermally stable —CF3 end groups. An example method of stabilization is exposure of the fluoropolymer to a fluorinating agent, such as elemental fluorine, for example by processes as disclosed in U.S. Pat. Nos. 4,742,122 and 4,743,658, the contents of which are incorporated here by reference in their entirety.

Non-fluorinated perfluorocopolymers typically have a higher dissipation factor than fluorinated perfluorocopolymers. The composition of the perfluorocopolymer matrix 110 can be tailored to achieve both a sufficiently low dielectric constant and low dissipation factor for the dielectric substrate 102 and sufficient adhesion to the quartz fabric 108 and the conductive cladding 104. For instance, the composition of the perfluorocopolymer matrix 110 can be tailored to provide as much fluorinated copolymer as possible while still maintaining sufficient adhesion to the quartz fabric 108 and the conductive cladding 104. A sufficiently low dielectric constant for the dielectric substrate 102 is a dielectric constant at 10 GHz of less than about 2.5, e.g., between 2.1 and 2.5, e.g., between 2.1 and 2.3. A sufficiently low dissipation factor for the dielectric substrate 102 is a dissipation factor at 10 GHz of less than 0.001, such as between 0.0002 and 0.001, e.g., between 0.0006 to 0.001, e.g., between 0.0006 and 0.0008. In some examples, the sufficiency of the adhesion between the perfluorocopolymer matrix 110 and the quartz fabric 108 and the conductive cladding 104 is determined by the peel strength between the dielectric substrate 102 and the conductive cladding 104. For instance, the adhesion is sufficient if the peel strength is greater than 2 lb./inch, e.g., greater than 4 lb./inch, e.g., between 2 and 20 lb./inch or between 4 and 20 lb./inch. In some examples, the sufficiency of the adhesion between the perfluorocopolymer matrix 110 and the quartz fabric 108 and the conductive cladding 104 is determined by the tendency of the flexible laminate 100 to resist formation of conductive anodic filaments (CAF), discussed further below.

In some examples, the composition of the perfluorocopolymer matrix 110 is indicated by a ratio (e.g., a weight or volume ratio) of fluorinated perfluorocopolymer to non-fluorinated perfluorocopolymer. The weight percentage of fluorinated perfluorocopolymer can be between 50% and 90%, such as between 50% and 80%, e.g., 50%, 60%, 70%, 75%, 80%, or 90%; and the weight percentage of non-fluorinated perfluorocopolymer can be between 10% and 50%, e.g., 10%, 20%, 25%, 30%, 40%, or 50%.

In some examples, the composition of the perfluorocopolymer matrix 110 is indicated by a number (e.g., a number concentration) of carboxyl end groups, present in the perfluorocopolymer matrix 110. Non-limiting examples of such carboxyl end groups include —COF, —CONH₂, —CO₂CH₃, and —CO₂H and are determined by polymerization aspects such as choice of polymerization medium, initiator, chain transfer agent, if any, and buffer if any. The number of carboxyl end groups per million carbon atoms present in the perfluorocopolymer matrix 100 can be between 30 and 70, e.g., between 35 and 65. This number of carboxyl end groups can be selected to achieve sufficient adhesion between the perfluorocopolymer matrix 110 and the quartz fabric 108 and the conductive cladding 104 while also achieving a sufficiently low dielectric constant and dissipation factor. For instance, the number of carboxyl end groups can be selected such that there is no CAF formation in the flexible laminate 100. In some examples, the composition of the fluorinated perfluorocopolymer and the non-fluorinated perfluorocopolymer are indicated by a number (e.g., a number concentration) of carboxyl end groups present in each type of perfluorocopolymer. The fluorinated perfluorocopolymer can have less than 10 carboxyl end groups per million carbon atoms, e.g., 5 or fewer, or 1 or fewer, or fewer than 1 carboxyl end groups per million carbon atoms. The non-fluorinated perfluorocopolymer can have between 100 and 300 carboxyl end groups per million carbon atoms, e.g., between 120 and 280 or between 150 and 250 carboxyl end groups per million carbon atoms. The analysis and quantification of carboxyl end groups in perfluorocopolymers can be carried out by infrared spectroscopy methods, such as described in U.S. Pat. Nos. 3,085,083, 4,742,122 and 4,743,658, the contents of all of which are incorporated here by reference in their entirety. The presence of the thermally stable end group —CF3 (the product of fluorination) is deduced from the absence of unstable end groups existing after the fluorine treatment. The presence of —CF3 end groups results in reduced dissipation factor of the perfluorocopolymer as compared to other end groups

The melt flow rate (MFR) of the fluorinated perfluorocopolymer, the non-fluorinated perfluorocopolymer, or both also can affect the adhesion between the perfluorocopolymer matrix 110 and the quartz fabric 108 and the conductive cladding 104. A polymer with a high MFR flows more readily during lamination of the flexible laminate 100 than can a polymer with a lower MFR. The flow of the perfluorocopolymer matrix 110 during the lamination process (discussed in more detail below) enables the perfluorocopolymer matrix 110 to fully encapsulate the fibers of the quartz fabric 108, resulting in a dielectric substrate 102 that is substantially free of voids, e.g., non-porous. A void-free dielectric substrate 102 is resistant to CAF formation. For instance, the MFR of the fluorinated perfluorocopolymer can be between 1 and 40 g/10 minutes, e.g., between 2 and 15 g/10 minutes, e.g., 2 g/10 minutes, 4 g/10 minutes, 6 g/10 minutes, 8 g/10 minutes, 10 g/10 minutes, 12 g/10 minutes, 14 g/10 minutes, 16 g/10 minutes, 18 g/10 minutes, 20 g/10 minutes, 25 g/10 minutes, 30 g/10 minutes, 35 g/10 minutes, or 40 g/10 minutes. The MFR of the non-fluorinated perfluorocopolymer can be between 1 and 40 g/10 minutes, e.g., between 2 and 20 g/10 minutes, e.g., 2 g/10 minutes, 5 g/10 minutes, 10 g/10 minutes, 15 g/10 minutes, or 20 g/10 minutes. The fluorinated and non-fluorinated perfluorocopolymers can be provided in a ratio that results in an overall MFR for the perfluorocopolymer matrix of between 10 and 30 g/10 minutes, e.g., 10 g/10 minutes, 15 g/10 minutes, 18 g/10 minutes, 21 g/10 minutes, 24 g/10 minutes, 27 g/10 minutes, or 30 g/10 minutes.

Suitable materials for the fluorinated tetrafluoroethylene/perfluoro(alkyl vinyl ether) perfluorocopolymer include a Teflon™ perfluoroalkane (PFA) 416HP with an MFR of about 40 g/10 minutes or a Teflon™ PFA 440HP (A/B) with an MFR of about 16 g/10 minutes or 14 g/10 minutes, respectively (The Chemours Company, Wilmington, DE). Suitable materials for the non-fluorinated tetrafluoroethylene/perfluoro(alkyl vinyl ether) include a Teflon™ PFA 316 with an MFR of about 40 g/10 minutes or a Teflon™ PFA 340 with an MFR of about 14 g/10 minutes (Chemours).

The fluorinated perfluorocopolymer, the non-fluorinated perfluorocopolymer, or both, have a high melting point, such as between 250° C. and 350° C., e.g., between 280° C. and 320° C., between 290° C. and 310° C., e.g., about 305° C. The high melting point of the fluorinated perfluorocopolymer, the non-fluorinated perfluorocopolymer, or both results in the perfluorocopolymer matrix 100 being resistant to high temperatures and provides the dielectric substrate 102 with a sufficient solder float resistance, such as a solder float resistance at 288° C. of at least 5 seconds, at least 10 seconds, at least 30 seconds, or at least 60 seconds, e.g., between 5 and 20 seconds, between 10 and 15 seconds, between 10 and 30 seconds, between 10 and 60 seconds, or between 30 and 60 seconds, as measured according to the IPC-TM-650 test method.

The composition of the perfluorocopolymer matrix 110 can be selected to enable the dielectric substrate 102 to be compatible with plasma treatment, e.g., for metallization of through-holes formed through the thickness of the flexible laminate 100.

Specific examples of fluorinated tetrafluoroethylene/perfluoro(alkyl vinyl ether) copolymers that are suitable for inclusion in the perfluorocopolymer matrix 100 include a Teflon™ perfluoroalkane (PFA) 416HP with an MFR of about 40 g/10 minutes or a Teflon™ PFA 440HP with an MFR of about 14 g/10 minutes (The Chemours Company, Wilmington, DE). Specific examples of non-fluorinated tetrafluoroethylene/perfluoro(alkyl vinyl ether) copolymers that are suitable for inclusion in the perfluorocopolymer matrix 100 include a Teflon™ PFA 316 with an MFR of about 40 g/10 minutes or a Teflon™ PFA 340 with an MFR of about 14 g/10 minutes (The Chemours Company).

In some examples, the perfluorocopolymer matrix 100 is formed of a single type of perfluorocopolymer having both fluorinated end groups and reactive end groups (e.g., rather than a mixture of a fluorinated perfluorocopolymer and a non-fluorinated perfluorocopolymer). The ratio of fluorinated end groups to reactive end groups in the single type of perfluorocopolymer is selected to achieve both sufficient adhesion between the perfluorocopolymer matrix 110 and the quartz fabric 108 and a sufficiently low dielectric constant and dissipation factor.

The presence of the woven quartz fabric 108 enables the CTE of the dielectric substrate 102 to be matched to the CTE of the metal foil 104. The woven quartz fabric 108 that is embedded in the perfluorocopolymer matrix 110 is formed of spread glass (e.g., quartz) bundles.

Quartz (silicon dioxide) has a lower CTE than the perfluorocopolymer matrix 110. By adjusting the ratio of the perfluorocopolymer matrix 110 to the woven glass fabric 108, the CTE of the dielectric substrate 102 in the x-y plane can be matched to the in-plane CTE of the metal foil 104, thereby providing the flexible laminate 100 with dimensional stability. For instance, the dielectric substrate 102 can include between 5 and 20 volume percent of woven quartz fabric 108 and between 80 and 95 volume percent of the perfluorocopolymer matrix 110 to the woven glass fabric 108. The CTE in the x-y plane of the dielectric substrate 102 can be between 5 and 25 ppm/° C., e.g., between 16 and 22 ppm/° C., e.g., between 14 and 20 ppm/° C., thereby providing a dimensional stability of less than about 0.1%. By contrast, the CTE of the perfluorocopolymer matrix 110 alone can be between 100 and 300 ppm/° C.

Quartz has a low dielectric constant (about 3.7 at 10 GHz) and low loss (about 0.0001 at 10 GHz), meaning that the dielectric substrate 102 has a low dielectric constant and low loss even with the presence of the quartz fabric embedded in the perfluorocopolymer matrix. The woven quartz fabric 108 has a thickness of less than about 30 μm, e.g., between 10 μm and 30 μm, helping a thin dielectric substrate 102 to be achieved. The basis weight of the quartz fabric 108 is less than about 50 g/m², e.g., less than about 25 g/m², e.g., between 10 g/m² and 25 g/m². In a specific example, the quartz fabric 108 is a 22 μm thick 1027C quartz glass (Shin-Etsu Quartz Products Co., Ltd., Tokyo, Japan).

In some examples, the woven quartz fabric 108 is subjected to one or more surface treatments to improve the wettability of the fibers of the woven quartz fabric 108 by the perfluorocopolymer matrix 110, to remove residual organic matter, or to mechanically alter the surface of the fibers to enhance adhesion between the fibers of the quartz fabric 108 and the perfluorocopolymer matrix 110. The objective of the surface treatment can be to facilitate substantially complete wetting of the fibers by the perfluorocopolymer such that the perfluorocopolymer fully encapsulates the quartz bundles. Sufficient encapsulation of and adhesion to the quartz bundles by the perfluorocopolymer enables the dielectric substrate 102 to be substantially free of voids, e.g., non-porous, which in turn helps prevent formation of conductive anodic filaments and occurrence of electromigration during post-processing, e.g., during formation of vias through the thickness of the flexible laminate 100.

The surface treatment can include a thermal treatment to remove residual organic matter (e.g., residual starches) from the surface of the quartz fibers such that a clean quartz surface is exposed to the perfluorocopolymer. The surface treatment can include the addition of adhesion promotors such as methacrylate silane, aminosilane, or fluorosilane on the surface of the quartz fibers. The surface treatment can include a plasma or corona treatment. The surface treatment can include treatment with a polymeric coating, such as a fluoropolymer, e.g., a perfluoroalkane (PFA), fluorinated ethylene propylene (FEP), or Teflon™ amorphous fluoropolymer, to form a polymer (e.g., fluoropolymer) film on the surface of the quartz fibers. For instance, the quartz fabric can be immersed in a solution containing a dispersion of the fluoropolymer to form a monolayer of the fluoropolymer on the surface of the quartz fibers. The surface treatment can include treatment with a fluorinated silane to form a layer, e.g., a monolayer, of fluorinated molecules on the surface of the quartz fibers. A combination of surface treatments can be applied, such as a thermal treatment followed by a plasma or corona treatment. The surface treatment(s) applied to the quartz fabric 108 can improve wettability of the fibers by the perfluorocopolymer matrix 110, enabling better encapsulation of the fibers of the quartz fabric 108 by the perfluorocopolymer matrix 110 and stronger adhesion between the perfluorocopolymer matrix 110 and the fibers of the quartz fabric 108, thereby contributing to formation of a void-free dielectric substrate 102 that is resistant to CAF formation.

The wettability of the quartz fabric can be characterized by the water contact angle (WCA). The woven quartz fabric following surface treatment can have a WCA of between 0° and 60°.

In some examples, particles, e.g., silica particles, are embedded in the perfluorocopolymer matrix 110 rather than the quartz fabric 108. The size and surface treatment of the particles are selected to achieve CTE matching with the metal foil 104 and to improve wettability of the particles by the perfluorocopolymer matrix 110.

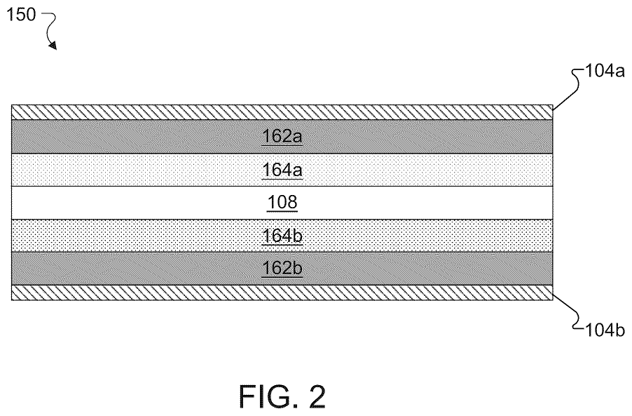

In some examples, the lamination structure can be designed to achieve good encapsulation of the quartz fabric, e.g., in addition to or instead of application of a surface treatment to the quartz fabric. Referring to FIG. 2, an example metal-clad, flexible laminate can be fabricated by laminating a set of layers 150. The set of layers includes multiple layers of fluoropolymer films, including a non-fluorinated tetrafluoroethylene/perfluoro(alkyl vinyl ether) layer 162a, 162b disposed on either side of a quartz fabric 108, and a perfluorocopolymer layer 164a, 164b that includes a fluorinated perfluorocopolymer and a non-fluorinated perfluorocopolymer disposed on the exterior-facing side of each non-fluorinated layer 162. A conductive cladding, such as the metal (e.g., copper) foil 104a, 104b described above), is disposed on both exterior sides of the set of layers 150. When the structure shown in FIG. 2 is laminated to produce a flexible laminate (see below for further discussion of lamination processes), the non-fluorinated layer 162 encapsulates the quartz fabric 108 such that the non-fluorinated layers 162 and the perfluorocopolymer layer 164 form a matrix in which the quartz fabric 108 is embedded, e.g., form a dielectric substrate for the flexible laminate.

Referring again to FIG. 1, the additive material 112 is dispersed, e.g., homogeneously dispersed, in the perfluorocopolymer matrix 110. The additive material 112 is a material that is capable of absorbing UV light such that the flexible laminate 100 can be processed by UV drilling processes, e.g., to form vias between the top and bottom surfaces 106 of the flexible laminate 100. The additive material 112 is present in the dielectric substrate 102 at a volume percentage of less than 2%, e.g., between 1 and 2 volume percent, e.g., 1 vol. %, 1.25 vol. %, 1.5 vol. %, or 2 vol. %. The additive material 112 can be a material that has a relatively low dielectric constant, e.g., a dielectric constant of between 10 and 1000, so that the inclusion of the additive material 112 in the perfluorocopolymer matrix 110 does not significantly increase the dielectric constant or dissipation factor of the dielectric substrate 102. For instance, the inclusion of the additive material 112 at less than 2% by volume can cause the dielectric constant of the dielectric substrate 102 to increase by less than 10%, e.g., less than 5% or less than 2%.

In some examples, the additive material 112 is inorganic particles, e.g., particles of cerium oxide (CeO₂), titanium dioxide (TiO₂), silicon dioxide (SiO₂), barium titanate (BaTiO₃), calcium titanate (CaTiO₃), zinc oxide (ZnO), or other suitable materials. The particles can have a diameter of less than about 5 μm, less than about 2 m, less than about 1 μm, or less than about 0.5 μm, e.g., between 0.1 μm and 0.5 μm. For instance, smaller particles often are more effective absorbers of UV light than larger particles of similar composition. In some examples, the additive material 112 is an organic (e.g., polymeric) additive, such as a low loss thermoset material such as polyimide, that is blended into the perfluorocopolymer matrix 110. In some examples, both inorganic particles and an organic additive are used as additive materials.

The copper foil 104 of the flexible laminate 100 provides a platform on which conductive patterns can be defined, e.g., such that the flexible laminate 100 can be used as a printed-wiring board. In some examples, the copper foil 104 is disposed on the surface(s) 106 of the dielectric substrate 102 by a mechanical process, e.g., a roll-to-roll lamination process. For instance, the copper foil can be an electrodeposited copper foil or a rolled copper foil. In some examples, the copper foil 104 is deposited, e.g., electrolytically plated onto the dielectric substrate 102.

The copper foil 104 has a thickness of less than about 72 μm, e.g., less than about 18 μm, e.g., between 10 μm and 18 μm. The copper foil 104 has a low root mean square (RMS) roughness, such as an RMS roughness of less than 1 μm, e.g., less than 0.5 μm, as measured by non-contact interferometry. The low RMS roughness of the copper foil 104 helps to maintain the low insertion loss of the circuitry made from the flexible laminate 100. In some examples, the RMS roughness of the copper foil 104 is selected to balance low insertion loss (e.g., achievable by a low RMS roughness) with good adhesion between the copper foil 104 and the dielectric substrate 102 (e.g., achievable by higher RMS roughness). For instance, as discussed above, a sufficiently high peel strength between the dielectric substrate 102 and the copper foil 104 is a peel strength that is greater than 2 lb./inch, e.g., greater than 4 lb./inch, e.g., between 2 and 20 lb./inch or between 4 and 20 lb./inch.

The copper foil 104 has a purity of at least about 99.9%. The surface chemistry of the copper foil 104 can be affected by surface treatments such as treatment with zinc, thermal stability additives, and treatments to resist oxidation. These surface treatments can be applied to one or both surfaces of the copper foil 104. Elements such as iron and zinc have been found to be effective in enhancing the peel strength without appreciably degrading the electrical performance of the substrate.

As discussed above, the dielectric substrate 102 of the flexible laminate 100 is substantially free of voids and has sufficient adhesion between the perfluorocopolymer matrix 110 and the quartz fabric 108, which enables the flexible laminate to resist formation of conductive anodic filaments (CAF). CAF are metallic filaments that form, e.g., in voids or weak areas of a dielectric substrate due to electromigration of metal induced by, e.g., application of an electric field. CAF formation can lead to electric failure, e.g., when the CAF create short-circuit pathways between vias through the printed-wiring board. A flexible laminate can be considered as having no CAF formation when there is less than a one decade drop in resistance throughout the duration of a test a resistance of greater than 10 MOhms after an initial 96 hour equilibration period. A CAF test can last up to 1000 hours or more with applied voltages of between 100 VDC and 1000 VDC, e.g., depending on application criteria.

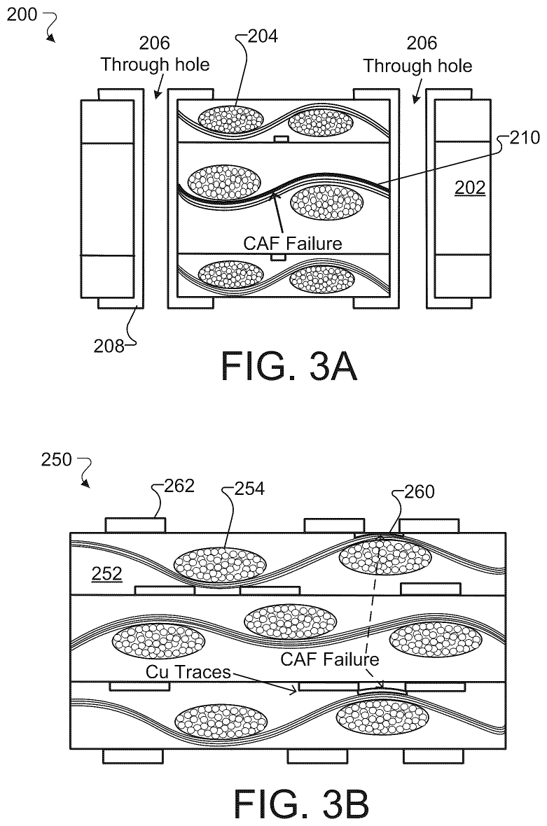

An example of CAF formation is shown in FIG. 3A. FIG. 3A shows a hypothetical laminate 200 having a dielectric matrix 202 with glass fibers 204 embedded therein. Through holes (also sometimes referred to as vias) 206 are formed through the thickness of the laminate 200 and plated with a metal 208, e.g., copper. Application of an electric field causes the metal 208 to anodically dissolve, migrate, and redeposit in the dielectric matrix 202, e.g., at interfaces between the dielectric matrix 202 and the glass fibers 204, forming filaments 210 that extend between adjacent vias 206.

FIG. 3B shows another example of CAF formation in a hypothetical laminate 250 having a dielectric matrix 252 with glass fibers 254 embedded therein and a conductor pattern 262, e.g., a copper pattern, defined on the top, bottom, and interior surfaces of the laminate 250. Filaments 260 of metal, e.g., copper, form at interfaces between the conductor pattern 262 and the glass fibers 254.

Referring again to FIG. 1, the dielectric substrate 102 of the flexible laminate is substantially void-free and has strong adhesion between the perfluorocopolymer matrix 110 and the quartz fabric 108. This is achieved, e.g., by the nature of the perfluorocopolymer (e.g., the number concentration of reactive end groups), the surface chemistry of the quartz fabric, and manufacturing parameters such as pressure and temperature (discussed below). In addition, the arrangement of the quartz fabric 108 in the perfluorocopolymer matrix 110 is such that there is substantially no contact between fibers of the fabric and the conductive cladding 104. As a result, CAF formation in the dielectric substrate 102 is minimal and the flexible laminate 100 can be used a reliable and robust printed-wiring board substrate.

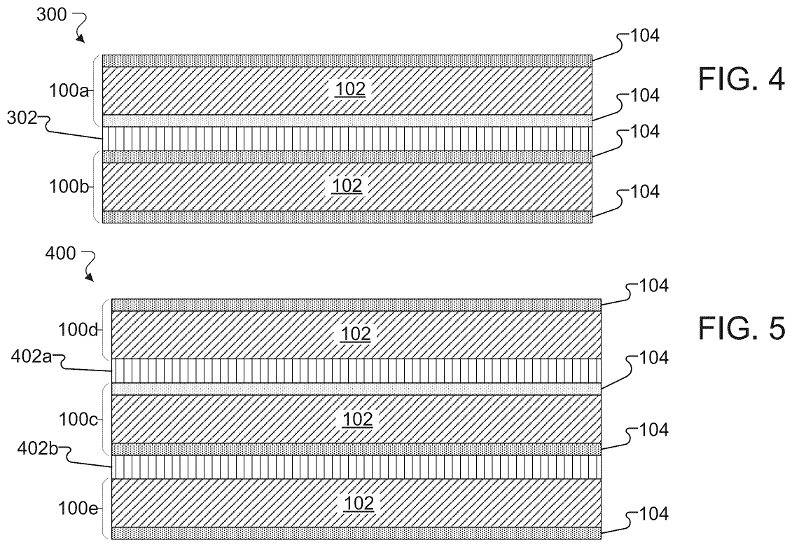

Referring to FIG. 4, a multilayer printed-wiring board 300 can be formed from multiple of the flexible laminates 100 described above. In the example of FIG. 4, the multilayer printed-wiring board 300 includes two flexible laminates 100a, 100b connected by an adhesive layer 302. Vias (also referred to as through-holes; not shown) can be defined through all or a portion of the thickness of the multilayer printed-wiring board, e.g., by UV drilling, with the UV energy being absorbed by the additive material in the dielectric substrate of the flexible laminate 100. The vias can be plated with a metal, such as a copper film. The adhesive layer 302 can be, e.g., an adhesive that can be bonded at a temperature below the melting point of the perfluorocopolymer matrix of the flexible laminate 100. In some examples, the adhesive is a thermoplastic adhesive that is capable of being bonded at a temperature between 0° C. and 50° C. less than the melting point of the perfluorocopolymer matrix. In some examples, the adhesive is a thermoset adhesive that is capable of being bonding at a temperature of between 0° C. and 200° C. less than the melting point of the perfluorocopolymer matrix, e.g., at temperatures between 150° C. and 250° C.

Referring to FIG. 5, multiple (here, three) flexible laminates 100 are laminated together to form a multi-layer printed-wiring board 400. A central flexible laminate 100c includes top and bottom conductive claddings. Flexible laminates 100d, 100e each includes a single conductive cladding. The flexible laminates 100c, 100d are bonded to the central flexible laminate 100e by adhesive layers 402a, 402b, respectively. The adhesive layers 402a, 402b can be, e.g., an adhesive that can be bonded at a temperature below the melting point of the perfluorocopolymer matrix of the flexible laminates 100. In some examples, the adhesive is a thermoplastic adhesive that is capable of being bonded at a temperature between 0° C. and 50° C. less than the melting point of the perfluorocopolymer matrix. In some examples, the adhesive is a thermoset adhesive that is capable of being bonding at a temperature of between 0° C. and 200° C. less than the melting point of the perfluorocopolymer matrix.

Vias (not shown) can be defined through all or a portion of the thickness of the multilayer printed-wiring board 400, e.g., by UV drilling.

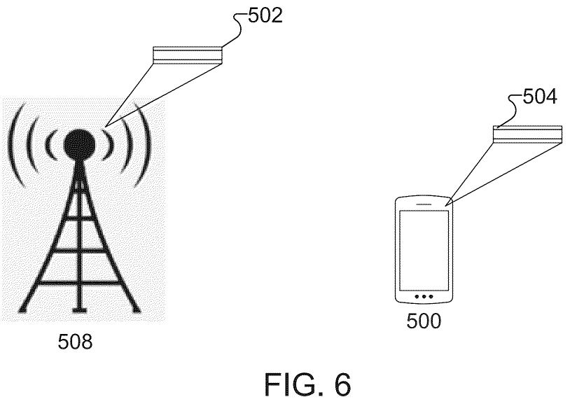

Printed-wiring boards made from the flexible laminates 100 described here can be used in various applications, e.g., high-frequency applications such as high-frequency communications applications. For instance, referring to FIG. 6, a printed-wiring board 502 including one or more flexible laminates can be used for an antenna or antenna feedline for a communication device 500 (e.g., a mobile communication devices) operable on a 5G communications network. For instance, flexible laminates can be useful as substrates for printed-wiring boards for communication device antennas or antenna feed lines to connect electronic components of the device that are located on different planes. A printed-wiring board 504 including one or more flexible laminates can be used in communications network equipment, such as in a transmission antenna in a tower 508 of a cellular communications network. Printed-wiring boards including flexible laminates can also be used in other applications, such as in camera feedlines in mobile computing devices.

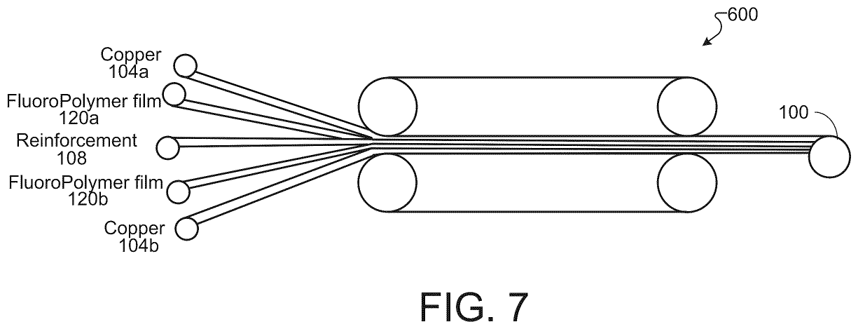

The flexible laminates described here can be manufactured by lamination processes. Referring to FIG. 7, in an example, the quartz fabric 108 is disposed between two perfluorocopolymer films 120a, 120b. Each perfluorocopolymer film 120a, 120b has a thickness of between 10 μm and 50 μm, e.g., between 20 μm and 30 μm. The conductive claddings 104a, 104b are disposed on respectively perfluorocopolymer film 120a, 120b. For example, the conductive claddings 104 are electrodeposited copper foils or rolled annealed copper foils. Each conductive cladding 104a, 104b has a thickness of less than about 72 μm, e.g., less than about 18 μm, e.g., between 10 μm and 18 μm.

The layers of material 104, 108, 120 are heated and compressed to consolidate the layers of the material, thereby forming the flexible laminate 100. In some examples, the quartz fabric 108 and the two perfluorocopolymer films 120a, 120b are laminated to form the dielectric substrate and the conductive cladding (e.g., copper foils) are electrodeposited onto the dielectric substrate in a second processing step.

The parameters of the lamination process (e.g., temperature, time, and pressure) are selected to achieve a target viscosity of the perfluorocopolymer that enables the perfluorocopolymer to flow, thereby wetting and encapsulating the glass bundles of the quartz fabric 108 and enabling good adhesion between the perfluorocopolymer and the conductive claddings 104. For instance, the process parameters are selected such that the perfluorocopolymer reaches a zero shear viscosity of between 2000 Pa-s and 5000 PA-s at 330° C. The temperature can be greater than the melting point of the perfluorocopolymer, e.g., between 10° C. and 30° C. higher than then the melting point of the perfluorocopolymer. For instance, the temperature can be between 300° C. and 400° C., e.g., between 320° C. and 330° C., e.g., 300° C., 320° C., 340° C., 360° C., 380° C., or 400° C. The temperature ramp rate can be between 1 and 5° C./minute, e.g., 1° C./minute, 2° C./minute, 3° C./minute, 4° C./minute, or ° C./minute. The pressure applied to the layers of material can be between 100 psi and 1000 psi, e.g., between 200 psi and 1000 psi or between 600 psi and 1000 psi. The dwell time (e.g., for a static lamination process) can be between 30 minutes and 120 minutes, e.g., 30 minutes, 60 minutes, 90 minutes, or 120 minutes.

FIG. 7 depicts an isobaric roll-to-roll lamination process using a set of rollers 600. In some examples, the roll-to-roll lamination process is an isochoric, gap-controlled lamination process. In some examples, the lamination process is a static lamination process in which the layers of material are pressed between heated platens.

The perfluorocopolymer films 120 are formed by, e.g., melt processing and extrusion. In some examples, the additive material is mixed into melted fluorinated perfluorocopolymer, and the mixture of fluorinated copolymer and additive material is mixed with melted non-fluorinated perfluorocopolymer. In some examples, the additive material is mixed into melted non-fluorinated perfluorocopolymer, and the mixture of non-fluorinated perfluorocopolymer and additive material is mixed with melted fluorinated perfluorocopolymer. The resulting perfluorocopolymer mixture is extruded to form the perfluorocopolymer films. Mixing the additive material with the non-fluorinated perfluorocopolymer helps with integration and dispersion of the additive material throughout the perfluorocopolymer film.

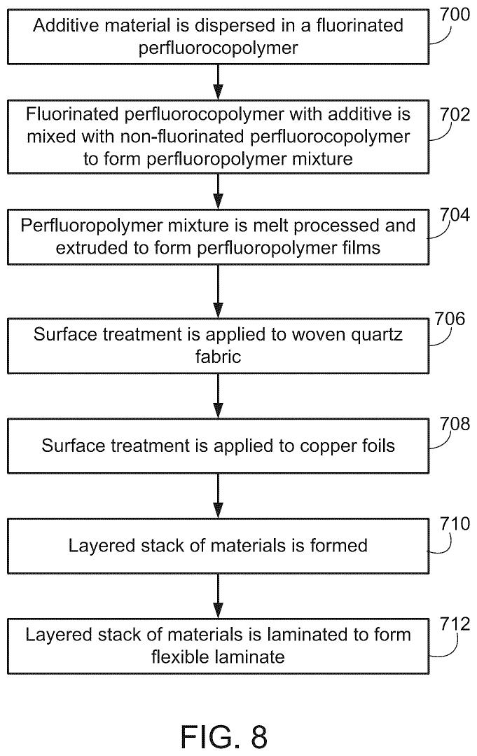

FIG. 8 is a flow chart of an example process for making the flexible laminate 100. An additive material that is capable of absorbing ultraviolet light is dispersed in a non-fluorinated perfluorocopolymer, such as a non-fluorinated tetrafluoroethylene/perfluoro(alkyl vinyl ether) perfluorocopolymer (700). The additive material is, e.g., particles of cerium oxide, titanium dioxide, silicon dioxide, barium titanate, calcium titanate, or zinc oxide; or a polymeric additive such as a polyimide. The non-fluorinated perfluorocopolymer with the dispersed additive material is mixed with a fluorinated perfluorocopolymer, such as a fluorinated tetrafluoroethylene/perfluoro(alkyl vinyl ether) perfluorocopolymer (702), to form a perfluorocopolymer mixture. The perfluorocopolymer mixture is melt processed and extruded to form perfluorocopolymer films (704).

A woven quartz fabric is exposed to a surface treatment, such as heat treatment, corona or plasma treatment, or formation of a coating on the surface of the fibers of the quartz fabric (706). Copper foils, e.g., electrodeposited copper foils or rolled annealed copper foils, are also exposed to a surface treatment, such as heat treatment, corona or plasma treatment, or deposition of adhesion promoters or thermal stability additives (708).

A layered stack of materials is formed (710) including the treated quartz fabric disposed between two perfluorocopolymer films, with a treated conductive cladding on both the top and the bottom of the stack. The layered stack of materials is laminated by application of heat and pressure to form a flexible laminate (712), e.g., in a static lamination process or a roll-to-roll lamination process.

### EXAMPLES

The following polymers and polymer dispersions are used in these examples.
PFA1: Teflon™ PFA 440HP (A/B) (Chemours), a high purity fluorinated perfluoroalkoxy (PFA) melt processable resin having an MFR of 16 g/10 min (for “A”) and 14 g/10 min (for “B).
PFA2: Teflon™ PFA 340 (Chemours), a general purpose non-fluorinated PFA melt processable resin having an MFR of 14 g/10 min.
PFA3: Teflon™ PFA 416HP (Chemours), high purity fluorinated PFA melt processable resin having an MFR of 40 g/10 min.
PFA-Dispersion1: Teflon™ PFA 335D (Chemours), which is an off-white aqueous PFA dispersion stabilized with a non-ionic surfactant and having an MFR of about 2 g/10 min.
PFA-Dispersion 2: A terpolymer of tetrafluoroethylene (TFE), perfluoro(ethyl vinyl ether) (PEVE) and allyl glycidyl ether (AGE), having an MFR of 12 g/10 min, a melting point of 244° C., a PEVE content of 15 wt. %, and an allyl glycidyl ether content of 0.1 wt. %. Manufacture of such terpolymer is described in U.S. Patent Application Publication US 2010/0036053A1, e.g., example 4, the contents of which are incorporated here by reference in their entirety.
PFA-Dispersion3: An off-white aqueous dispersion of Teflon™ PFA 940HP Plus (Chemours) stabilized with a non-ionic surfactant and having an MFR of about 16 g/10 min.

### Example 1: Characterization of Flexible Copper Clad Laminates

PFA films of various types were combined with 1027C-04 quartz fabric from Shin-Etsu and 12 μm thick BHFX-P92C-HG rolled copper foil from JX Nippon Mining & Metals Corporation (Tokyo, Japan) to form flexible copper clad laminates. PFA films were extruded from PFA1 and/or PFA2 polymers manufactured by Chemours. These grades were blended in order to achieve a desired ratio of fluorinated to non-fluorinated perfluorocopolymers. In some cases cerium oxide (Sigma Aldrich, St. Louis, MO) was added to evaluate the UV absorption properties of the composite. Materials were laminated in a hot oil vacuum press at a peak temperature of 320° C. and a pressure of 200 psi. Testing was performed in accordance with the procedures outlined in Table 1.

TABLE 1
Overview of experimental targets and test methods.

| Property | Target | Direction | Units | Test Conditions | Test Method |
|---|---|---|---|---|---|
| Dielectric | <2.5 | Z | | 23° C., 50% RH | IPC TM-650 |
| constant (DK) | | | | | 2.5.5.13 |
| Dissipation | <0.0010 | Z | | 23° C., 50% RH | IPC TM-650 |
| factor (DF) | | | | | 2.5.5.13 |
| Coefficient of | 17 ± 3 | X (MD) | ppm/° C. | 25° C. to 250° C. | IPC TM-650 |
| thermal | 17 ± 3 | Y (CMD) | | | 2.4.41 |
| expansion | — | Z | | | |
| Copper peel | >4 | Z | pli | various copper foils | IPC TM-650 |
| strength | | | | | 2.4.8 |
| Dimensional | <±0.1 | MD | % | After etch + bake | IPC TM-650 |
| stability | <±0.1 | CMD | % | | 2.2.4c |
| Thickness | 50-60 | Z | μm | After etch | IPC TM-650 |
| | | | | | 2.2.18 |
| Solder float | Pass | — | — | 288° C./60 sec | IPC TM-650 |
| resistance | | | | | 2.4.13 |
| Sharpie wicking | <0.5 | — | mm | 0.125″ holes, IPA | Internal test |
| | | | | wiped surface | |
| Resin content | — | — | % | as manufactured | IPC TM-650 |
| | | | | | 2.3.16.1c |
| Melt flow rate | — | — | g/10 | 372° C. | ASTM D3307 |
| (MFR) | | | min | | |
| Carboxyl end | — | — | #/10⁶ | FTIR based | Internal test |
| group | | | carbon | | |
| determination | | | atoms | | |

The details of the experimental configuration including materials used and process conditions are shown in Tables 2A and 2B. The five values in the “Construction” column refer to the thickness of the copper cladding on each side of the laminate (12 μm in this example), the thickness of the perfluorocopolymer films used to create the laminate (25 μm in this example; constructed from two ply 12.5 μm PFA films), and type of glass fabric (1027 glass in this example). Prior to testing, samples were allowed to equilibrate at 23° C. and 50% relative humidity for 24 hours.

TABLE 2A
Experimental details.

| | Material Details | | | | | |
|---|---|---|---|---|---|---|
| | | | | | | Carboxyl |
| | | | | | Film | End |
| Run ID | Construction | Copper | Film | Glass | MFR | Groups |
| G2-13-1 | 12/25/1027/25/12 | 12 μm BHFX- | 12.5 μm PFA1 | 1027C-04 | 14 | ~0 |
| | | P92C-HG | | | | |
| G2-13-2 | 12/25/1027/25/12 | 12 μm BHFX- | 12.5 μm | 1027C-04 | 14 | ~140-150 |
| | | P92C-HG | PFA1/PFA2 | | | |
| | | | 25/75 | | | |
| G2-13-3 | 12/25/1027/25/12 | 12 μm BHFX- | 12.5 μm | 1027C-04 | 14 | ~75-100 |
| | | P92C-HG | PFA1/PFA2 | | | |
| | | | 50/50 | | | |
| G2-13-4 | 12/25/1027/25/12 | 12 μm BHFX- | 12.5 μm PFA2 | 1027C-04 | 14 | ~190-200 |
| | | P92C-HG | | | | |
| G2-13-5 | 12/25/1027/25/12 | 12 μm BHFX- | 12.5 μm PFA1- | 1027C-04 | 14 | ~0 |
| | | P92C-HG | CeO2-1 | | | |
| G2-13-6 | 12/25/1027/25/12 | 12 μm BHFX- | 12.5 μm PFA1- | 1027C-04 | 14 | ~0 |
| | | P92C-HG | CeO2-2 | | | |

TABLE 2B
Process conditions.

| | Lamination parameters | | | | |
|---|---|---|---|---|---|
| | Dwell | Pressure, | Dwell | | Ramp rate, |
| Run ID | temp, C. | psi | time, min | Vacuum | C./min |
| G2-13-1 | 320 | 200 | 60 | 1 atm | 2 |
| G2-13-2 | 320 | 200 | 60 | 1 atm | 2 |
| G2-13-3 | 320 | 200 | 60 | 1 atm | 2 |
| G2-13-4 | 320 | 200 | 60 | 1 atm | 2 |
| G2-13-5 | 320 | 200 | 60 | 1 atm | 2 |
| G2-13-6 | 320 | 200 | 60 | 1 atm | 2 |

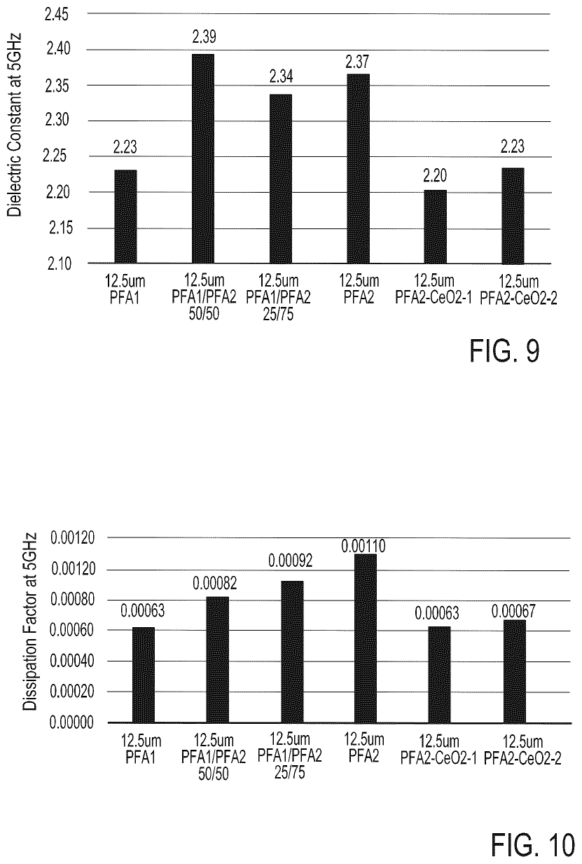

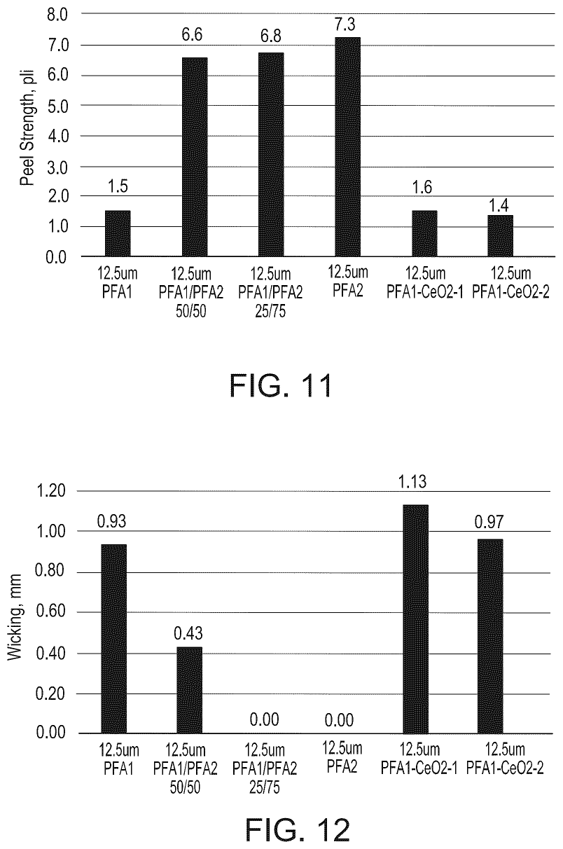

The data obtained from the experiments detailed in Tables 2A-2B are shown in Table 3 and in FIGS. 9-12. Specifically, FIGS. 9 and 10 show dielectric constant and dissipation factor results, respectively, at 5 GHz. FIG. 11 shows machine direction (MD) peel strength test results. FIG. 12 shows results from a Sharpie wicking test.

In a Sharpie wicking test, a hole is formed in the flexible laminate, a Sharpie® permanent marker is rubbed around the edge of the hole, and the hole is cleaned with isopropanol to remove excess ink. The radial distance away from the edge of the hole to which the ink was wicked is measured. Without being bound by theory, it is believed that this wicking test serves as an indicator of the adhesion between the fibers of the quartz fabric and the perfluorocopolymer matrix; poor adhesion or poor encapsulation leaves voids into which the ink can wick, resulting in a longer travel distance. By contrast, a substrate with good adhesion and good encapsulation will exhibit a low wicking distance.

TABLE 3
Experimental test data for the experiment detailed in Tables 2A-2B.

| | | | | Average | Average | | |
|---|---|---|---|---|---|---|---|
| | | | | etched | etched | | |
| | | | MD Peel | Thickness | thickness | Solder | Resin |
| | DK @, | DF @, | Strength | (copper | (etched), | Float | Content, |
| Run ID | 5 GHz | 5 GHz | As-Is, pli | clad), μm | μm | (288 C./60 s) | % |
| G2-13-1 | 2.23 | 0.00063 | 1.5 | 84.0 | 62.4 | Pass | 87.1% |
| G2-13-3 | 2.39 | 0.00082 | 6.6 | 89.3 | 66.3 | Pass | 89.3% |
| G2-13-2 | 2.34 | 0.00092 | 6.8 | 90.0 | 67.8 | Pass | 89.1% |
| G2-13-4 | 2.37 | 0.00110 | 7.3 | 86.3 | 66.4 | Pass | 88.1% |
| G2-13-5 | 2.20 | 0.00063 | 1.6 | 84.8 | 71.9 | Pass | 87.0% |
| G2-13-6 | 2.23 | 0.00067 | 1.4 | 79.3 | 64.6 | Pass | 87.0% |

These results show that films containing blends of carboxylated end groups achieve higher copper peel strength values at the expense of electrical performance (dissipation factor). These results also show the importance of carboxylated end groups in order to achieve sufficiently low and/or zero sharpie wicking results, which is a primary indicator of glass bundle penetration effectiveness.

### Example 2: Characterization of Flexible Copper Clad Laminates

PFA films of various types were combined with 1027C-04 quartz fabric from Shin-Etsu and 18 μm thick C110 CopperBond rolled copper foil from Wieland (Louisville, KY) to form flexible copper clad laminates. PFA films were extruded from PFA1 (fluorinated PFA) and/or PFA2 (non-fluorinated PFA) grades manufactured by Chemours. These grades were blended in order to achieve a desired ratio of fluorinated to non-fluorinated perfluorocopolymers. In some cases cerium oxide (Sigma Aldrich) or titanium dioxide (Chemours) was added to evaluate the UV absorption properties of the composite. Materials were laminated in a hot oil vacuum press at a peak temperature of 320° C. and a pressure of 200 psi, with a dwell time of 60 minutes, a vacuum of 1 atm, and a ramp rate of 2° C./min. Testing was performed in accordance with the procedures previously outlined in Table 1. The details of the experimental configuration including materials used for two sets of experiments are shown in Table 4.

TABLE 4
Experimental details.

| | Material Details | | | | | |
|---|---|---|---|---|---|---|
| | | | | | Film | Carboxyl |
| Run ID | Construction | Copper | Film | Glass | MFR | End Groups |
| G2-4-1 | 18/25/1027/25/18 | 18 μm C110 CB | 12.5 μm PFA1 | 1027C-04 | 14 | ~0 |
| G2-4-2 | 18/25/1027/25/18 | 18 μm C110 CB | 12.5 μm PFA1/PFA2 | 1027C-04 | 14 | ~140-150 |
| G2-4-3 | 18/25/1027/25/18 | 18 μm C110 CB | 12.5 μm PFA1/PFA2 | 1027C-04 | 14 | ~75-100 |
| G2-4-4 | 18/25/1027/25/18 | 18 μm C110 CB | 12.5 μm PFA2 | 1027C-04 | 14 | ~190-200 |
| G2-4-5 | 18/25/1027/25/18 | 18 μm C110 CB | 12.5 μm PFA1-CeO2-1 | 1027C-04 | 14 | ~0 |
| G2-4-6 | 18/25/1027/25/18 | 18 μm C110 CB | 12.5 μm PFA1-CeO2-2 | 1027C-04 | 14 | ~0 |
| G2-4-7 | 18/25/1027/25/18 | 18 μm C110 CB | 12.5 μm TiO2-1 | 1027C-04 | 14 | ~60 |
| G2-5-1 | 18/12.5/1027/12.5/18 | 18 μm C110 CB | 12.5 μm PFA1 | 1027C-04 | 14 | ~0 |
| G2-5-2 | 18/12.5/1027/12.5/18 | 18 μm C110 CB | 12.5 μm PFA1/PFA2 | 1027C-04 | 14 | ~140-150 |
| G2-5-3 | 18/12.5/1027/12.5/18 | 18 μm C110 CB | 12.5 μm PFA1/PFA2 | 1027C-04 | 14 | ~75-100 |
| G2-5-4 | 18/12.5/1027/12.5/18 | 18 μm C110 CB | 12.5 μm PFA2 | 1027C-04 | 14 | ~190-200 |
| G2-5-5 | 18/12.5/1027/12.5/18 | 18 μm C110 CB | 12.5 μm PFA1-CeO2-1 | 1027C-04 | 14 | ~0 |
| G2-5-6 | 18/12.5/1027/12.5/18 | 18 μm C110 CB | 12.5 μm PFA1-CeO2-2 | 1027C-04 | 14 | ~0 |
| G2-5-7 | 18/12.5/1027/12.5/18 | 18 μm C110 CB | 12.5 μm TiO2-1 | 1027C-04 | 14 | ~60 |

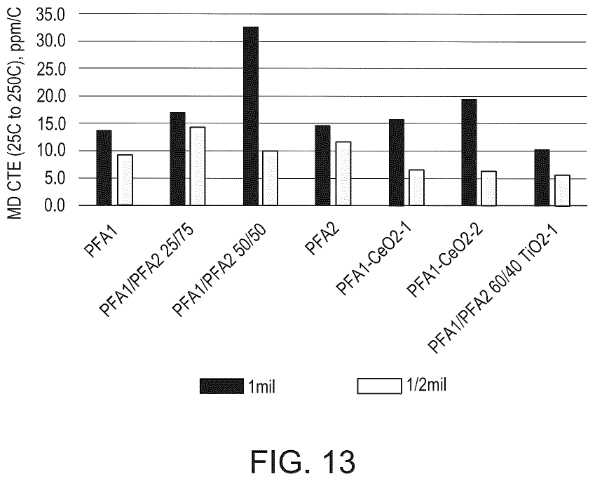

The data obtained from these two sets of experiments are shown in Table 5 and in FIG. 13, which shows machine direction CTE (AMD CTE) test results. Transverse CTE (CAMII CTE) was also measured. These results again show that films containing blends of carboxylated end groups achieve higher peel strength values at the expense of electrical performance (dissipation factor). These results also show again the importance of carboxylated end groups in order to achieve sufficiently low and/or zero sharpie wicking results, which is a primary indicator of glass bundle penetration effectiveness. Finally, these results show that a film thickness of 25 μm combined with the 1027C-04 quartz fabric achieves a CTE result close to 17 ppm/° C.

TABLE 5A
Experimental test data for the experiments detailed in Table 4.

| | | | MD Peel | |
|---|---|---|---|---|
| | | | Strength | Peel Failure |
| Run ID | DK @ 5 GHz | DF @ 5 GHz | As-Is, pli | Mode |
| G2-4-1 | 2.21 | 0.00047 | 1.3 | M (mixed) |
| G2-4-2 | 2.44 | 0.00077 | 3.9 | C (cohesive) |
| G2-4-3 | 2.38 | 0.00056 | 4.2 | C |
| G2-4-4 | 2.23 | 0.00080 | 4.4 | C |
| G2-4-5 | 2.37 | 0.00050 | 1.4 | M |
| G2-4-6 | 2.43 | 0.00048 | 1.1 | M |
| G2-4-7 | 2.36 | 0.00072 | 5.2 | C |
| G2-5-1 | 2.50 | 0.00066 | 1.2 | A (adhesive) |
| G2-5-2 | 2.50 | 0.00077 | 3.6 | A |
| G2-5-3 | 2.38 | 0.00074 | 4.6 | C |
| G2-5-4 | 2.24 | 0.00080 | 4.2 | C |
| G2-5-5 | 2.39 | 0.00052 | 1.3 | M |
| G2-5-6 | 2.52 | 0.00059 | 1.3 | M |
| G2-5-7 | 2.48 | 0.00081 | 2.8 | M |

TABLE 5B
Experimental test data for the experiments detailed in Table 4.

| | Average D/E | Average D/E | | | MD CTE | CMD CTE |
|---|---|---|---|---|---|---|
| | Thickness | thickness | | | (25 C. to | (25 C. to |
| | (copper clad), | (etched), | Solder Float | Sharpie | 250 C.), | 250 C.), |
| Run ID | μm | μm | (288 C./60 s) | wicking | ppm/C. | ppm/C. |
| G2-4-1 | 99.0 | 62.9 | Pass | 0.00 | 13.8 | |
| G2-4-2 | 102.2 | 68.3 | Pass | 0.00 | 17.1 | |
| G2-4-3 | 105.0 | 67.8 | Pass | 0.00 | 32.8 | |
| G2-4-4 | 99.2 | 66.0 | Pass | 0.00 | 14.8 | 18.0 |
| G2-4-5 | 100.0 | 62.5 | Pass | 0.46 | 15.7 | 19.4 |
| G2-4-6 | 92.2 | 59.5 | Pass | 0.50 | 19.5 | 27.4 |
| G2-4-7 | 91.2 | 57.4 | Pass | 0.40 | 10.3 | 14.4 |
| G2-5-1 | 75.4 | 30.3 | Pass | 0.80 | 9.4 | |
| G2-5-2 | 73.0 | 36.5 | Pass | 0.00 | 14.4 | 9.6 |
| G2-5-3 | 214.2 | 39.1 | Pass | 0.00 | 10.0 | 10.2 |
| G2-5-4 | 70.6 | 43.1 | Pass | 0.00 | 11.9 | 7.3 |
| G2-5-5 | 68.0 | 36.5 | Pass | 0.48 | 6.7 | 5.3 |
| G2-5-6 | 67.8 | 32.1 | Pass | 0.42 | 6.4 | |
| G2-5-7 | 66.6 | 35.0 | Pass | 0.33 | 5.8 | |

### Example 3: Characterization of Flexible Copper Clad Laminates

Fully fluorinated extruded films of PFA1 polymer were combined with 1027C-04 quartz fabric from Shin-Etsu and 18 μm thick Cl 10 CopperBond rolled copper foil from Wieland (Louisville, KY) to form flexible copper clad laminates. Materials were laminated in a continuous isobaric double belt press at a peak temperature of 320° C. and various pressures up to 80 bar. Testing was performed in accordance with the procedures previously outlined in Table 1. The details of the experimental configuration including materials used and process conditions are shown in Tables 6A and 6B.

TABLE 6A
Experimental details.

| | Material Details | | | | | |
|---|---|---|---|---|---|---|
| | | | | | Film | Carboxyl |
| Run ID | Construction | Copper | Film | Glass | MFR | End Groups |
| G2-8-1 | 18/25/1027/25/18 | 18 μm C110 CB | 25 μm PFA1 | 1027C-04 | 14 | ~0 |
| G2-8-2 | 18/25/1027/25/18 | 18 μm C110 CB | 25 μm PFA1 | 1027C-04 | 14 | ~0 |
| G2-8-3 | 18/25/1027/25/18 | 18 μm C110 CB | 25 μm PFA1 | 1027C-04 | 14 | ~0 |
| G2-8-4 | 18/25/1027/25/18 | 18 μm C110 CB | 25 μm PFA1 | 1027C-04 | 14 | ~0 |
| G2-8-5 | 18/25/1027/25/18 | 18 μm C110 CB | 25 μm PFA1 | 1027C-04 | 14 | ~0 |

TABLE 6B
Process conditions

| | Lamination parameters | | |
|---|---|---|---|
| | Heating Zone | Belt | Line Speed, |
| Run ID | Temp, C. | Pressure, bar | m/min |
| G2-8-1 | 320 | 10 | 1 |
| G2-8-2 | 320 | 20 | 1 |
| G2-8-3 | 320 | 40 | 1 |
| G2-8-4 | 320 | 60 | 1 |
| G2-8-5 | 320 | 80 | 1 |

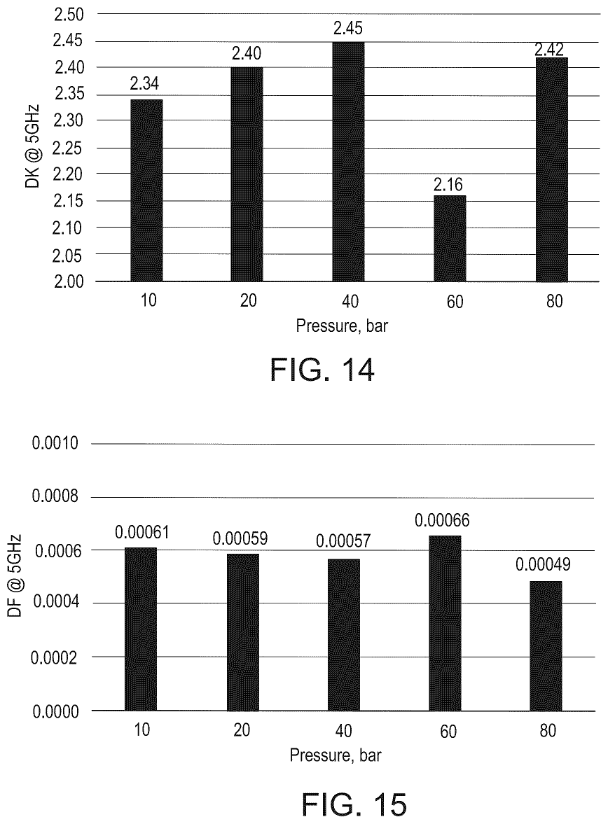

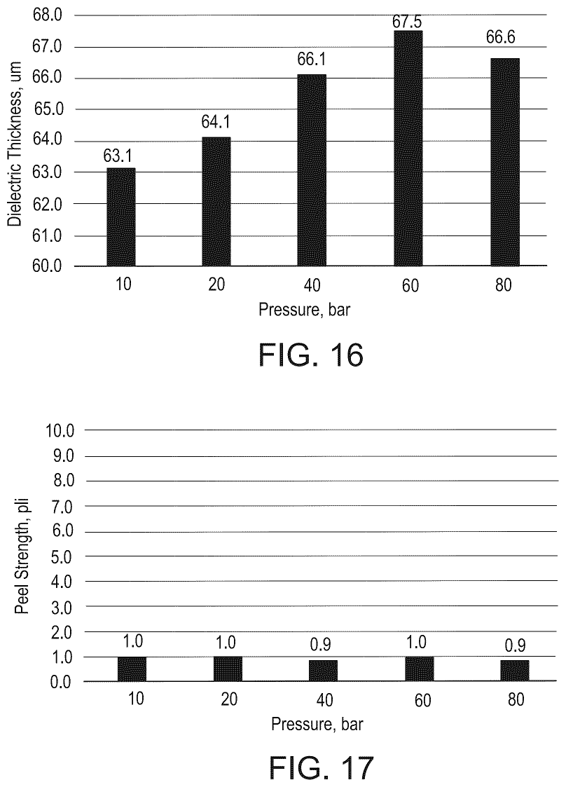

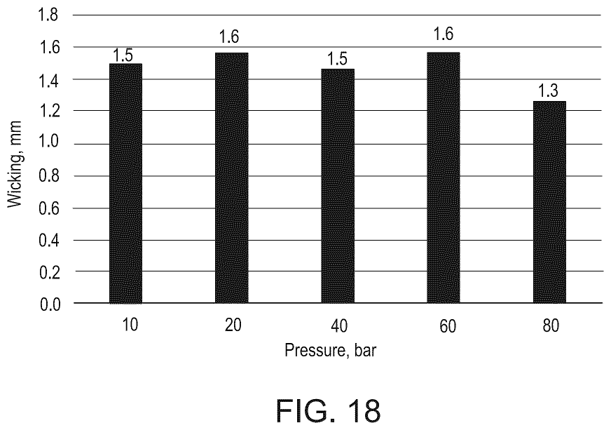

The data obtained from these experiments are shown in Tables 7A and 7B and in FIGS. 14-18. Specifically, FIGS. 14 and 15 show dielectric constant and dissipation factor results, respectively, at 5 GHz. FIG. 16 shows results of a thickness test, FIG. 17 shows peel strength test results, and FIG. 18 shows results from a Sharpie wicking test. These results demonstrate that films containing very low levels of carboxylated end groups achieve very poor glass bundle penetration (wicking) and very low levels of copper to dielectric adhesion.

TABLE 7A
Experimental test data for the experiment detailed in Table 6.

| | | | MD Peel | MD Peel |
|---|---|---|---|---|
| | DK @ | DF @ | Strength As-Is, | Strength After |
| Run ID | 5 GHz | 5 GHz | pli | Solder, pli |
| G2-8-1 | 2.34 | 0.00061 | 1.0 | 0.8 |
| G2-8-2 | 2.40 | 0.00059 | 1.0 | 1.0 |
| G2-8-3 | 2.45 | 0.00057 | 0.9 | 0.9 |
| G2-8-4 | 2.16 | 0.00066 | 1.0 | 0.9 |
| G2-8-5 | 2.42 | 0.00049 | 0.9 | 0.9 |

TABLE 7B
Experimental test data for the experiment detailed in Table 6.

| | Average D/E | | | |
|---|---|---|---|---|
| | Thickness | Average D/E | Solder Float | Sharpie |
| Run ID | (copper clad), μm | thickness, mils | (288 C./60 s) | Wicking |
| G2-8-1 | 101.8 | 63.1 | Pass | 1.5 |
| G2-8-2 | 102.6 | 64.1 | Pass | 1.6 |
| G2-8-3 | 101.2 | 66.1 | Pass | 1.5 |
| G2-8-4 | 101.2 | 67.5 | Pass | 1.6 |
| G2-8-5 | 102.0 | 66.6 | Pass | 1.3 |

### Example 4: Characterization of Flexible Copper Clad Laminates

PFA films of various types were combined with 1027C-04 quartz fabric from Shin-Etsu and 12 μm thick BHFX-P92C-HG rolled copper foil from JX Nippon to form flexible copper clad laminates. PFA films were extruded from PFA1 (fluorinated PFA), PFA3(fluorinated PFA), or PFA2 (non-fluorinated PFA) grades manufactured by Chemours. These grades were blended in order to achieve a desired ratio of fluorinated to non-fluorinated perfluorocopolymers. In some cases cerium oxide (Sigma Aldrich) or titanium dioxide (Chemours) was added to evaluate the UV absorption properties of the composite. Materials were laminated in a hot oil vacuum press at a peak temperature of 320° C. and a pressure of 200 psi, with a dwell time of 60 minutes, a vacuum of 1 atm, and a ramp rate of 2° C./min. Testing was performed in accordance with the procedures previously outlined in Table 1. The details of the experimental configuration including materials used are shown in Table 8.

TABLE 8
Experimental details.

| | Material Details | | | | | |
|---|---|---|---|---|---|---|
| | | | | | Film | Carboxyl |
| Run ID | Construction | Copper | Film | Glass | MFR | End Groups |
| G2-14-1 | 12/25/1027/25/12 | 12 μm BHFX- | 25 μm PFA3/PFA2 | 1027C-04 | 23 | ~75-100 |
| | | P92C-HG | 50/50 | | | |
| G2-14-2 | 12/25/1027/25/12 | 12 μm BHFX- | 25 μm PFA3/PFA2 | 1027C-04 | 30 | ~45-50 |
| | | P92C-HG | 75/25 | | | |
| G2-14-3 | 12/25/1027/25/12 | 12 μm BHFX- | 25 μm PFA3/PFA2 | 1027C-04 | 27 | ~45-50 |
| | | P92C-HG | 75/25-CeO2 | | | |
| G2-14-4 | 12/25/1027/25/12 | 12 μm BHFX- | 25 μm PFA3/PFA2 | 1027C-04 | 17 | ~45-50 |
| | | P92C-HG | 75/25-R101-1.25 | | | |
| G2-14-5 | 12/25/1027/25/12 | 12 μm BHFX- | 25 μm PFA3/PFA2 | 1027C-04 | 17 | ~45-50 |
| | | P92C-HG | 75/25-R103-1.25 | | | |
| G2-14-6 | 12/25/1027/25/12 | 12 μm BHFX- | 25 μm PFA3/PFA2 | 1027C-04 | 23 | ~45-50 |
| | | P92C-HG | 75/25-R103/CeO2- | | | |
| | | | 0.5/2.0 | | | |
| G2-14-7 | 12/25/1027/25/12 | 12 μm BHFX- | 25 μm PFA1-R101- | 1027C-04 | 14 | ~0 |
| | | P92C-HG | 2.5 | | | |
| G2-14-8 | 12/25/1027/25/12 | 12 μm BHFX- | 25 μm PFA1-R103- | 1027C-04 | 14 | ~0 |
| | | P92C-HG | 2.5 | | | |

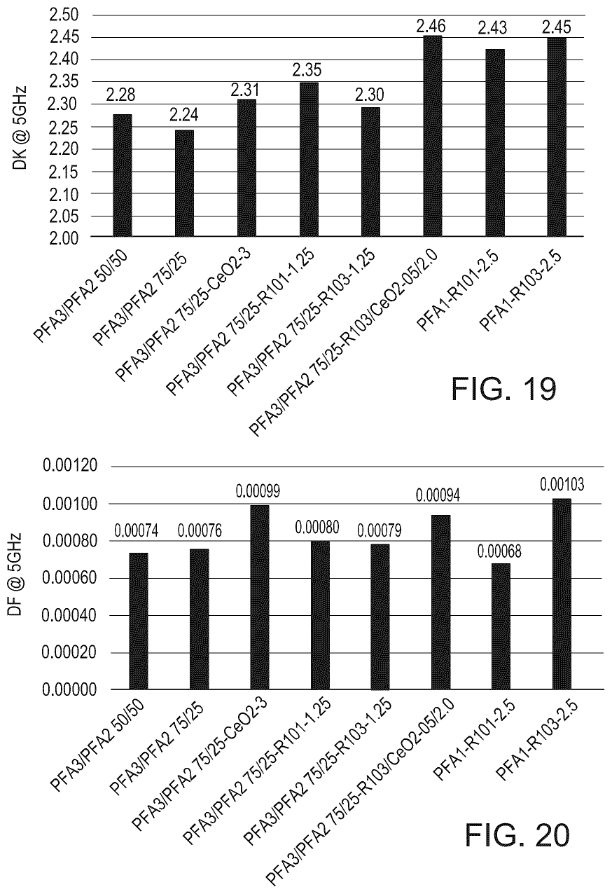

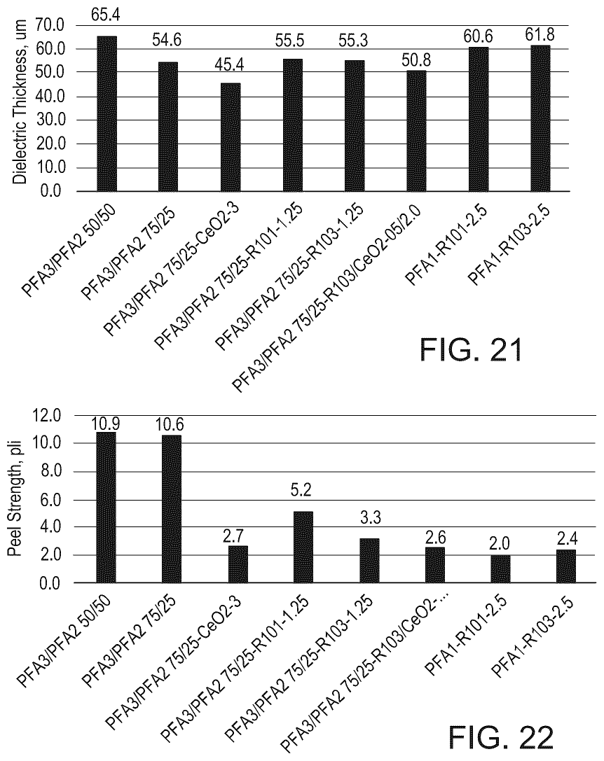

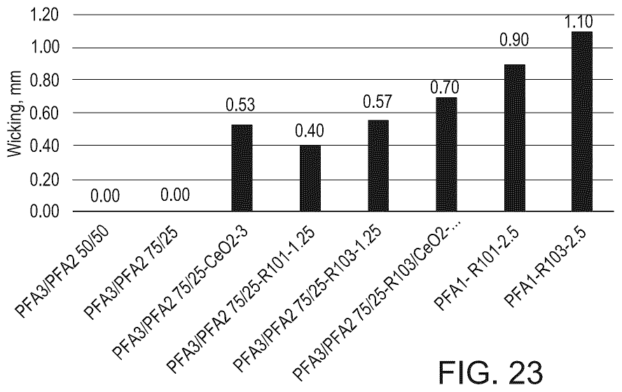

The data obtained from these experiments are shown in Table 9 and in FIGS. 19-23. Specifically, FIGS. 19 and 20 show dielectric constant and dissipation factor results, respectively, at 5 GHz. FIG. 21 shows results of a thickness test, FIG. 22 shows peel strength test results, and FIG. 23 shows results from a Sharpie wicking test. Estimated squeeze-out is measured by measuring the film flow distance from the edge of the laminate when squeezed.

TABLE 9
Experimental test data for the experiment detailed in Table 8.

| | | | | Average D/E | Average D/E | | | |
|---|---|---|---|---|---|---|---|---|
| | | | MD Peel | Thickness | thickness | | | Estimated |
| | DK @ | DF @ | Strength | (copper clad), | (etched), | Solder Float | Sharpie | squeeze-out, |
| Run ID | 5 GHz | 5 GHz | As-Is, pli | μm | μm | (288 C./60 s) | Wicking | inches |
| G2-14-1 | 2.28 | 0.00074 | 10.9 | 83.0 | 65.4 | Pass | 0.00 | 0 |
| G2-14-2 | 2.24 | 0.00076 | 10.6 | 80.2 | 54.6 | Pass | 0.00 | 0 |
| G2-14-3 | 2.31 | 0.00099 | 2.7 | 67.6 | 45.4 | Pass | 0.53 | 0 |
| G2-14-4 | 2.35 | 0.00080 | 5.2 | 74.6 | 55.5 | Pass | 0.40 | 0 |
| G2-14-5 | 2.30 | 0.00079 | 3.3 | 77.6 | 55.3 | Pass | 0.57 | 0 |
| G2-14-6 | 2.46 | 0.00094 | 2.6 | 72.6 | 50.8 | Pass | 0.70 | 0 |
| G2-14-7 | 2.43 | 0.00068 | 2.0 | 77.8 | 60.6 | Pass | 0.90 | 0 |
| G2-14-8 | 2.45 | 0.00103 | 2.4 | 78.4 | 61.8 | Pass | 1.10 | 0 |

These results demonstrate the strong impact of the presence of filler on peel strength and glass bundle wetting (sharpie wicking). These experiments indicate that higher MFR fluorinated resin (PFA3 (fluorinated) grade, MFR=40) when combined with carboxylated end groups improve the glass wetting and adhesion to copper foil. These results also show that the R101 titania particle (Chemours) was preferred versus the R103 titania particle (Chemours) based on both dissipation factor and wicking.

### Example 5: Characterization of Flexible Copper Clad Laminates

A blended PFA film having a resin matrix composition of 75 wt. % 416 (fluorinated) and 25 wt. % 340 (non-fluorinated) grades and filler loading of 1.25 vol. % R101 titania (Chemours) was combined with spread 106 electronic grade greige glass fabric from JPS Composite Materials (Anderson, SC) and 12 μm thick BHFX-P92C-HG rolled copper foil from JX Nippon to form flexible copper clad laminates. In some cases the glass fabric was heat treated (HT106SE) before lamination in order to thermally degrade and remove the residual starch sizing on the fabric. The fabric heat treatment was performed in a convection oven at 700° F. for 30 minutes. Also, the 106SE and HT106SE fabrics were coated prior to use with a thin layer (approx. 1-5 gsm) of a variety of commercial and experimental PFA materials form Chemours in order to assess the impact of glass surface coatings on resin wetting ability and interfacial adhesion. One configuration was made using the 1027C-04 quartz from Shin-Etsu as a control. Materials were laminated in a hot oil vacuum press at a peak temperature of 320° C. and a pressure of 600 psi, with a dwell time of 60 minutes, a vacuum of 1 atm, and a ramp rate of 2° C./min. Testing was performed in accordance with the procedures previously outlined in Table 1. The details of the experimental configuration including materials used and process conditions are shown in Table 10.

TABLE 10
Experimental details.

| | Material Details | | | | | |
|---|---|---|---|---|---|---|
| | | | | | Film | Carboxyl |
| Run ID | Construction | Copper | Film | Glass | MFR | End Groups |
| G2-21-1 | 12/25/106/25/12 | 12 μm BHFX- | 25 μm PFA3/PFA2 | HT106SE/PFA- | 17 | ~45-50 |
| | | P92C-HG | 75/25-R101-1.25 | Dispersion1 | | |
| G2-21-2 | 12/25/106/25/12 | 12 μm BHFX- | 25 μm PFA3/PFA2 | 106SE/PFA- | 17 | ~45-50 |
| | | P92C-HG | 75/25-R101-1.25 | Dispersion1 | | |
| G2-21-3 | 12/25/106/25/12 | 12 μm BHFX- | 25 μm PFA3/PFA2 | HT106SE/PFA- | 17 | ~45-50 |
| | | P92C-HG | 75/25-R101-1.25 | Dispersion3 | | |
| G2-21-4 | 12/25/106/25/12 | 12 μm BHFX- | 25 μm PFA3/PFA2 | 106SE/PFA- | 17 | ~45-50 |
| | | P92C-HG | 75/25-R101-1.25 | Dispersion3 | | |
| G2-21-5 | 12/25/106/25/12 | 12 μm BHFX- | 25 μm PFA3/PFA2 | HT106SE/PFA- | 17 | ~45-50 |
| | | P92C-HG | 75/25-R101-1.25 | Dispersion2 | | |
| G2-21-6 | 12/25/106/25/12 | 12 μm BHFX- | 25 μm PFA3/PFA2 | 106SE/PFA- | 17 | ~45-50 |
| | | P92C-HG | 75/25-R101-1.25 | Dispersion2 | | |
| G2-21-9 | 12/25/1027/25/12 | 12 μm BHFX- | 25 μm PFA3/PFA2 | 1027C-04 | 17 | ~45-50 |
| | | P92C-HG | 75/25-R101-1.25 | | | |

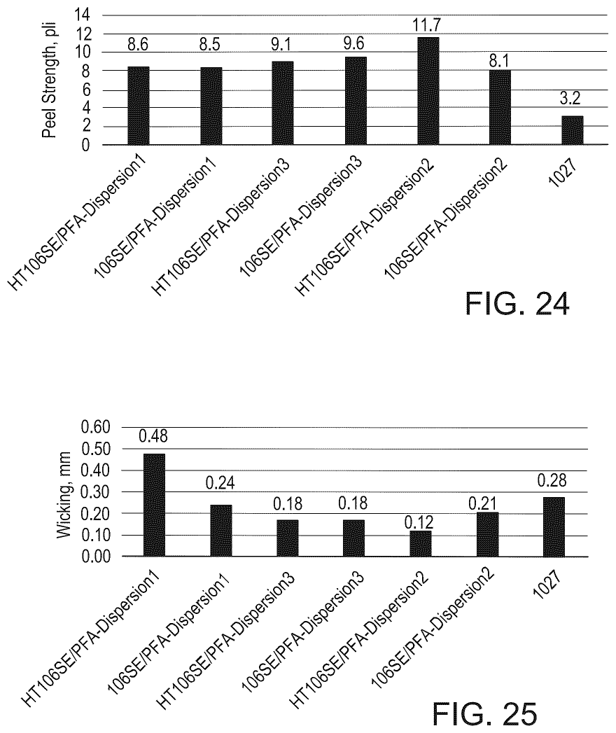

The data obtained from this experiment are shown in Table 11 and FIGS. 24 and 25, which show peel strength test results and Sharpie wicking results, respectively. This experiment demonstrated overall improvements in adhesion to both the copper foil and the glass interface as evidenced by higher peel strength numbers and overall lower sharpie wicking results.

TABLE 11
Experimental test data for the experiment detailed in Table 10.

| | | Average D/E | Average D/E | | | | Glass |
|---|---|---|---|---|---|---|---|
| | MD Peel | Thickness | thickness | | | Estimated | Resin |
| | Strength | (copper clad), | (etched), | Solder Float | Sharpie | squeeze-out, | Content, |
| Run ID | As-Is, pli | μm | μm | (288 C./60 s) | Wicking | inches | % |
| G2-21-1 | 8.6 | 81.8 | 57.9 | Pass | 0.48 | 0.13 | 85.7% |
| G2-21-2 | 8.5 | 79.4 | 59.1 | Pass | 0.24 | 0.19 | 86.7% |
| G2-21-3 | 9.1 | 78.0 | 54.9 | Pass | 0.18 | 0.13 | 85.9% |
| G2-21-4 | 9.6 | 77.8 | 53.4 | Pass | 0.18 | 0.13 | 85.9% |
| G2-21-5 | 11.7 | 80.6 | 58.5 | Pass | 0.12 | 0.13 | 85.4% |
| G2-21-6 | 8.1 | 80.6 | 57.9 | Pass | 0.21 | 0.13 | 86.0% |
| G2-21-9 | 3.2 | 76.8 | 53.1 | Pass | 0.28 | 0.13 | 84.8% |

### Example 6: Water Contact Angle Characterizations

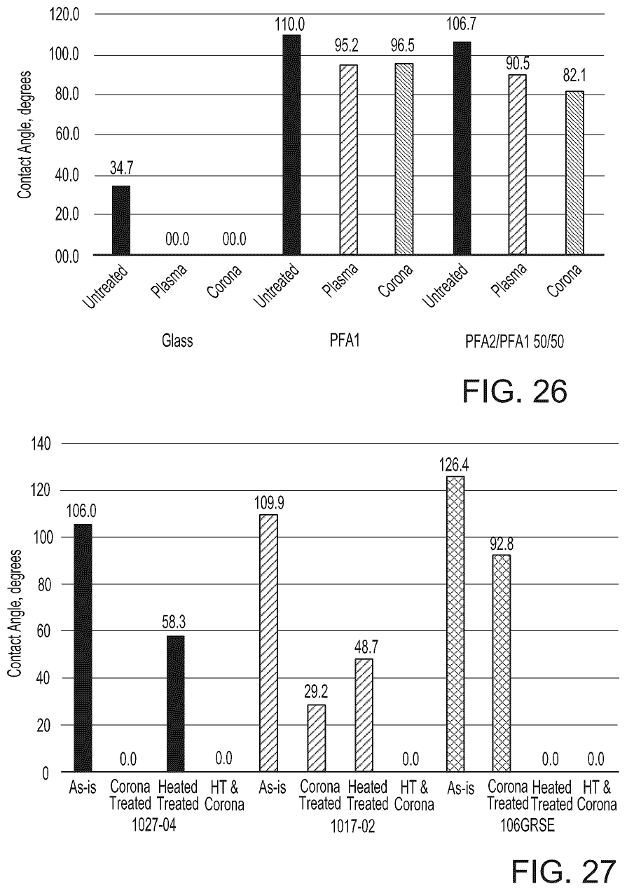

The effects of surface treatments on various polymeric films and reinforcements were studied. Water contact angle measurements were made using a VCA Optima goniometer (AST Products, Billerica, MA) with edge detection and angle analysis software to assist in the assessments. Atmospheric corona treatment was performed using a laboratory treater from Electro-Technic Products Inc. (Chicago, IL). Plasma treatment using air as the gas medium was performed using an Atto low pressure plasma system from Diener Electronic GmbH & Co. (Ebhausen, Germany). Surfaces studied were glass, PFA1 PFA film, PFA1/PFA2 blended PFA film at 50 wt % of each component, 1027C-04 quartz fabric from Shin-Etsu, 1017C-02 quartz fabric from Shin-Etsu, and spread 106 greige fabric from JPS Composite Materials. The results of these treatments are shown in FIGS. 26 and 27. Specifically, FIG. 26 shows water contact angle measurements of glass and PFA films before and after plasma and corona treatment. FIG. 27 shows water contact angle measurements of quartz and glass fabrics before and after plasma and corona treatment. A clear and significant improvement in wetting ability of the glass reinforcements was demonstrated while the PFA films showed some improvements as well.

### Example 7: Characterization of Flexible Copper Clad Laminates

A blended PFA film having a resin matrix composition of 75 wt. % 416 (fluorinated) and 25 wt. % 340 (non-fluorinated) grades and filler loading of 1.25 vol. % R101 titania (Chemours) was combined with a variety of glass fabric types and 12 μm thick BHFX-P92C-HG rolled copper foil from JX Nippon to form flexible copper clad laminates. The glass fabrics used are described in Table 12 blow.

TABLE 12
Description of glass fabrics.

| | | | | Heat | Corona | |
|---|---|---|---|---|---|---|
| Run ID | Glass | Supplier | Surface Treatment | Treatment? | Treatment? | Comments |
| G2-22-1 | 1027C-04 | Shin-Etsu | Methacrylate Silane | No | No | Control |
| G2-22-2 | HT1027C-04 | Shin-Etsu | Methacrylate Silane | Yes | No | — |
| G2-22-3 | HTC1027C-04 | Shin-Etsu | Methacrylate Silane | Yes | Yes | — |
| G2-22-4 | 1017C-02 | Shin-Etsu | Amino Silane | No | No | — |
| G2-22-5 | 106SE/AF2400 | JPS Composite | None (greige) | No | No | Coated Teflon AF |
| | | Materials | | | | on fabric |
| G2-22-6 | HT106SE/AF2400 | JPS Composite | None (greige) | Yes | No | |
| | | Materials | | | | |
| G2-22-7 | 1027C-04 + PFA2 | Shin-Etsu | Methacrylate Silane | No | No | Added an additional |
| G2-22-8 | HTC1027C-04 + | Shin-Etsu | Methacrylate Silane | Yes | Yes | layer of PFA2 film |
| | PFA2 | | | | | against the fabric |
| | | | | | | in the construction |

The fabric heat treatment was performed in a convection oven at 700° F. for 30 minutes. Atmospheric corona treatment was performed using a laboratory treater from Electro-Technic Products. Materials were laminated in a hot oil vacuum press at a peak temperature of 320° C. and a pressure of 600 psi, with a dwell time of 60 minutes, a vacuum of 1 atm, and a ramp rate of 2° C./min. Testing was performed in accordance with the procedures previously outlined in Table 1. The details of the experimental configuration including materials used are shown in Table 13.

TABLE 13
Experimental details and process conditions.

| | Material Details | | | | | |
|---|---|---|---|---|---|---|
| | | | | | Film | Carboxyl |
| Run ID | Construction | Copper | Film | Glass | MFR | End Groups |
| G2-22-1 | 12/25/1027/25/12 | 12 μm BHFX- | 25 μm PFA3/PFA2 | 1027C-04 | 17 | ~45-50 |
| | | P92C-HG | 75/25-R101-1.25 | | | |
| G2-22-2 | 12/25/1027/25/12 | 12 μm BHFX- | 25 μm PFA3/PFA2 | HT1027C-04 | 17 | ~45-50 |
| | | P92C-HG | 75/25-R101-1.25 | | | |
| G2-22-3 | 12/25/1027/25/12 | 12 μm BHFX- | 25 μm PFA3/PFA2 | HTC1027C-04 | 17 | ~45-50 |
| | | P92C-HG | 75/25-R101-1.25 | | | |
| G2-22-4 | 12/25/1027/25/12 | 12 μm BHFX- | 25 μm PFA3/PFA2 | 1017C-04 | 17 | ~45-50 |
| | | P92C-HG | 75/25-R101-1.25 | | | |
| G2-22-5 | 12/25/1027/25/12 | 12 μm BHFX- | 25 μm PFA3/PFA2 | 106SE/AF2400 | 17 | ~45-50 |
| | | P92C-HG | 75/25-R101-1.25 | | | |
| G2-22-6 | 12/25/1027/25/12 | 12 μm BHFX- | 25 μm PFA3/PFA2 | HT106SE/AF2400 | 17 | ~45-50 |
| | | P92C-HG | 75/25-R101-1.25 | | | |
| G2-22-7 | 12/25/1027/25/12 | 12 μm BHFX- | 25 μm PFA3/PFA2 | 1027C-04 + PFA2 | 17 | ~45-50 |
| | | P92C-HG | 75/25-R101-1.25 + | | | |
| | | | 12.5 μm PFA2 | | | |
| G2-22-8 | 12/25/1027/25/12 | 12 μm BHFX- | 25 μm PFA3/PFA2 | HTC1027C-04 + | 17 | ~45-50 |
| | | P92C-HG | 75/25-R101-1.25 + | PFA2 | | |
| | | | 12.5 μm PFA2 | | | |

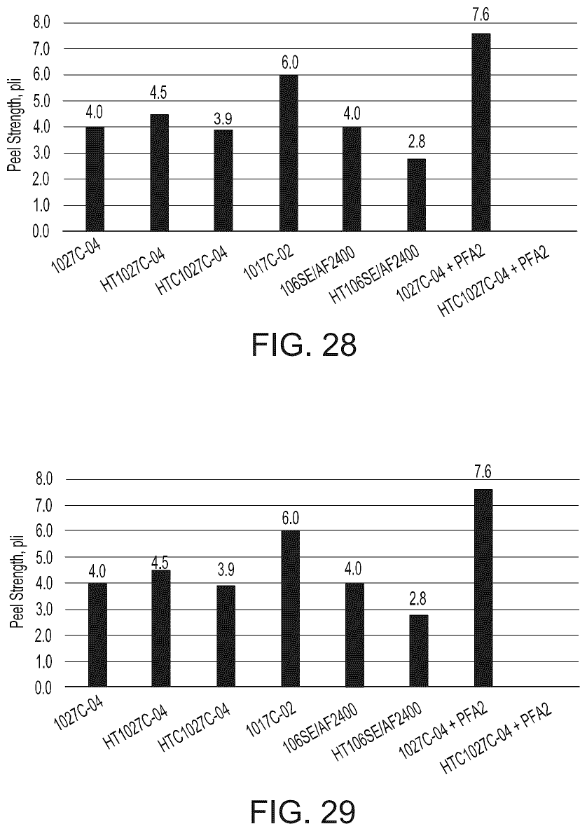

The data obtained from this experiment are shown in Table 14 and FIGS. 28 and 29, which show peel strength results and Sharpie wicking results, respectively. This experiment demonstrated adequate adhesion to the copper foil as well as improvements to the glass interface as evidenced by overall lower sharpie wicking results. Specifically, the 1017C-02 and HTC1027C-04+340 samples showed greatly improved wicking results.

TABLE 14
Experimental test data for the experiment detailed in Table 13.

| | | Average D/E | Average D/E | | | |
|---|---|---|---|---|---|---|
| | MD Peel | Thickness | thickness | | | Estimated |
| | Strength | (copper clad), | (etched), | Solder Float | Sharpie | squeeze-out, |
| Run ID | As-Is, pli | μm | μm | (288 C./60 s) | Wicking | inches |
| G2-22-1 | 4.0 | 77.6 | 54.6 | Pass | 0.28 | 0.13 |
| G2-22-2 | 4.5 | 73.2 | 54.4 | Pass | 0.19 | 0.19 |
| G2-22-3 | 3.9 | 73.4 | 54.1 | Pass | 0.26 | 0.13 |
| G2-22-4 | 6.0 | 73.2 | 54.8 | Pass | 0.10 | 0.13 |
| G2-22-5 | 4.0 | 78.8 | 58.1 | Pass | 0.29 | 0.13 |
| G2-22-6 | 2.8 | 80.4 | 60.5 | Pass | 0.36 | 0.13 |
| G2-22-7 | 7.6 | 104.0 | 79.3 | Pass | 0.14 | 0.25 |
| G2-22-8 | | 93.6 | 76.4 | Pass | 0.00 | 0.50 |

### Example 8: Insertion Loss Characterization

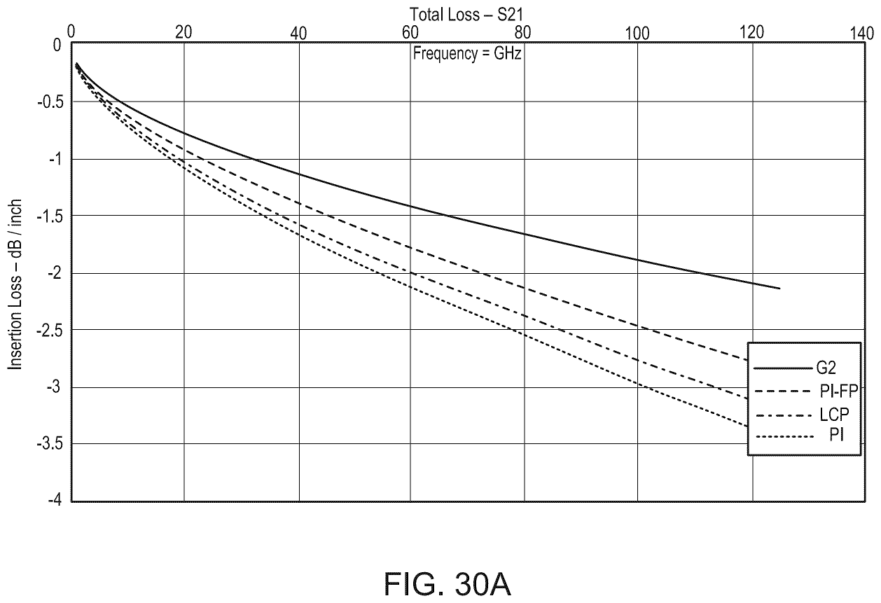

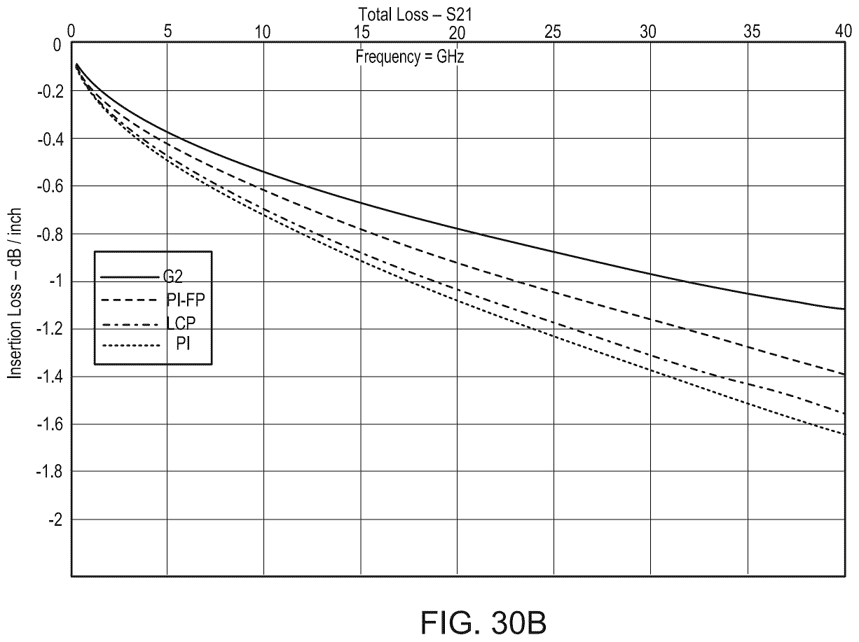

The insertion loss was modeled for the flexible laminate 100 described above, having a 50 μm thick dielectric substrate, and for other commercially available laminate materials, including polyimide and fluoropolymer (PI-FP), Liquid Crystal Polymer (LCP), and Polyimide (PI). FIGS. 30A and 30B show modeled insertion loss for the flexible laminate (marked as “G2”) and for the other laminate materials. These plots show the increased insertion loss that can be achieved due to the electrical properties of the dielectric substrate 102 of the flexible laminate 100.

### Example 9: Elemental and Roughness Characterization of Copper Foils

Copper foils were analyzed using Energy Dispersive X-Ray Analysis (EDX). The two copper foils analyzed were 12 μm BHFX-P92C-HG from JX Nippon and 18 μm BF-NN-HT from Circuit Foil Luxembourg (Wiltz, Luxembourg). EDX results are shown in Tables 15 and 16. Elementally, the coppers were found to have expected surface treatments which enhance thermal stability (Zn). It is generally understood that the presence of very low levels of low ferromagnetic elements (e.g., Fe, Ni, Co) enables low insertion loss to be achieved. These results show that both copper foils that were characterized contain low ferromagnetic levels.

TABLE 15
EDX analysis results for 12 μm BHFX-P92C-HG copper foil.

| BHFX-P92C-HG | C | O | Si | Cr | Fe | Co | Ni | Cu | Zn |
|---|---|---|---|---|---|---|---|---|---|
| Max | 4.06 | 1.32 | 0.3 | 0.46 | 0.12 | 2.17 | 0.66 | 95.88 | 0.6 |
| Min | 2.35 | 0.65 | 0.13 | 0.21 | 0 | 0.87 | 0.55 | 90.9 | 0 |
| Average | 3.39 | 1 | | | 0.04 | 1.61 | | 93.15 | |
| Std. Deviation | 0.47 | 0.25 | | | 0.04 | 0.39 | | 1.61 | |

TABLE 16
EDX analysis results for 18 μm BF-NN-HT copper foil.

| BF-NN-HT | C | O | Si | P | S | Cr | Fe | Ni | Cu | Zn |
|---|---|---|---|---|---|---|---|---|---|---|
| Max | 3.31 | 3.17 | 0.22 | 0.5 | 0.24 | 0.36 | 0.09 | 1.21 | 93.03 | 1.88 |
| Min | 2.76 | 2.02 | 0.22 | 0.27 | 0.17 | 0.27 | 0 | 0.81 | 89.46 | 0.77 |
| Average | 3.06 | 2.41 | | 0.41 | | | 0.04 | 1.05 | 91.27 | 1.4 |
| Std. Deviation | 0.2 | 0.5 | | 0.09 | | | 0.04 | 0.16 | 1.47 | 0.52 |

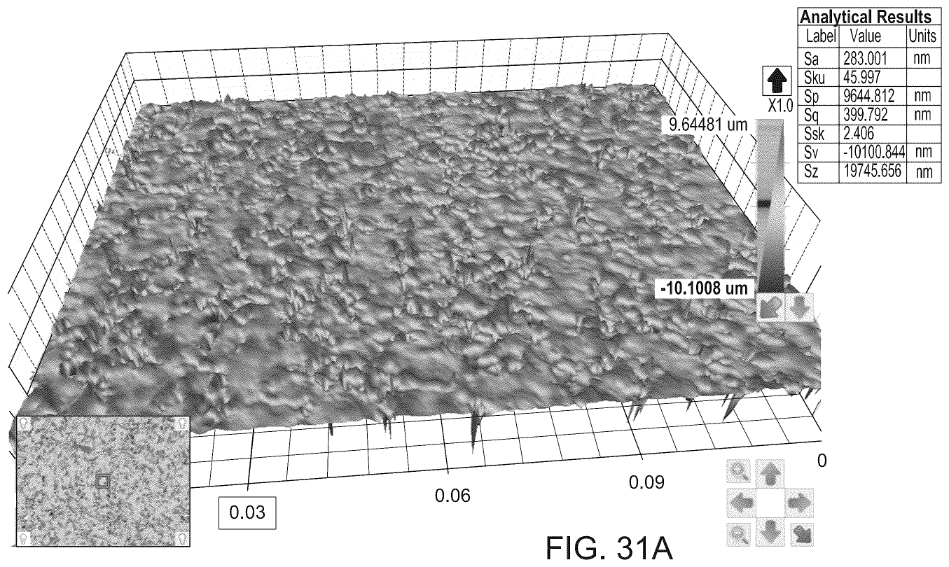

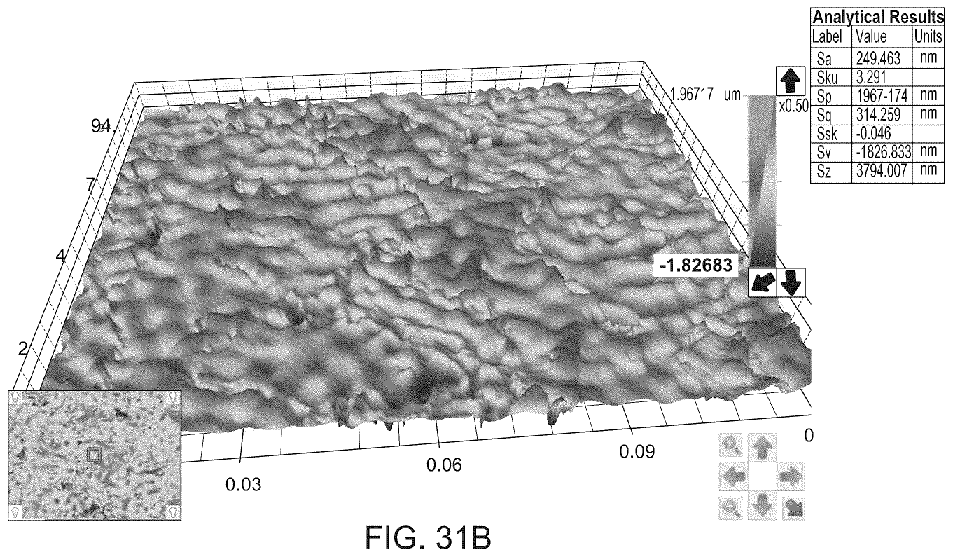

Copper foils were also analyzed using a Bruker ContourGT white light interferometer to characterize their surface roughness. FIGS. 31A and 31B show representative three-dimensional (3D) results, at 50× magnification, of the roughness scan for BHFX-P92C-HG and BF-NN-HT copper foil, respectively. The results of a larger number of surface roughness scans are tabulated in Table 17. Supplier A is Circuit Foils Luxembourg, Supplier B is Wieland, and Supplier C is JX Nippon. In Table 17, Sa is the arithmetical mean height, Sku is the kurtosis, Sp is the maximum peak height, Sq is the root mean square peak height, Ssk is the skewness, Sv is the maximum pit height, and Sz is the maximum height.

TABLE 17
White light interferometry copper roughness data.

| | | | Sa | Sku | Sp | Sq | Ssk | Sv | Sz |
|---|---|---|---|---|---|---|---|---|---|
| Supplier | Grade | Mag. | μm | μm | μm | μm | μm | μm | μm |
| A | 18 μm BF-NN-HT | 20X | 0.14 | 0.00 | 0.67 | 0.18 | 0.00 | −0.64 | 1.33 |
| A | 18 μm BF-NN-HT | 20X-2 | 0.17 | 0.00 | 1.80 | 0.22 | 0.00 | −1.86 | 3.65 |
| A | 18 μm BF-NN-HT | 50X | 0.10 | 0.00 | 0.67 | 0.13 | 0.00 | −1.08 | 1.75 |
| A | 18 μm BF-NN-HT | 50X-2 | 0.25 | 0.00 | 1.97 | 0.31 | 0.00 | −1.83 | 3.79 |
| A | 18 μm BF-TZA | 20X | 0.49 | 0.00 | 3.08 | 0.62 | 0.00 | −2.59 | 5.67 |
| A | 18 μm BF-TZA | 20X-2 | 0.54 | 0.00 | 8.68 | 0.68 | 0.00 | −6.84 | 15.52 |
| A | 18 μm BF-TZA | 50X | 0.55 | 0.00 | 4.71 | 0.69 | 0.00 | −2.98 | 7.69 |
| A | 18 μm BF-TZA | 50X-2 | 0.59 | 0.01 | 10.21 | 0.78 | 0.00 | −9.53 | 19.74 |
| B | 18 μm C110 CB | 20X | 0.64 | 0.00 | 3.85 | 0.81 | 0.00 | −3.34 | 7.19 |
| B | 18 μm C110 CB | 20X-2 | 0.44 | 0.00 | 3.03 | 0.57 | 0.00 | −12.41 | 15.44 |
| B | 18 μm C110 CB | 50X | 0.37 | 0.00 | 2.26 | 0.47 | 0.00 | −3.21 | 2.47 |
| B | 18 μm C110 CB | 50X-2 | 0.41 | 0.01 | 12.40 | 0.55 | 0.00 | −10.60 | 23.00 |
| C | 12 μm | 20X | 0.24 | 0.01 | 2.93 | 0.34 | 0.00 | −2.00 | 4.94 |
| | BHFX-P92C-HA-V2 | | | | | | | | |
| C | 12 μm | 50X | 0.27 | 0.01 | 9.66 | 0.36 | 0.00 | −3.10 | 12.76 |
| | BHFX-P92C-HA-V2 | | | | | | | | |
| C | 12 μm | 20X | 0.23 | 0.01 | 3.40 | 0.33 | 0.00 | −2.27 | 5.67 |
| | BHFX-P92C-HG | | | | | | | | |
| C | 12 μm | 50X | 0.28 | 0.05 | 9.64 | 0.40 | 0.00 | −10.10 | 19.75 |
| | BHFX-P92C-HG | | | | | | | | |

### Example 10: Effect of End Group Content on Copper Clad Laminates

The effects of end group content on copper clad laminate properties were evaluated by preparing PFA1 (fluorinated PFA) and PFA2 (non-fluorinated PFA) resins combined with R101 titania (Chemours) at various ratios of PFA2 to PFA1. Mixtures of ˜70 grams of resin were dry blended and then fed into a Rheometer Services Inc. (Wall, NJ) System 10 batch mixer outfitted with a 60 cc volume mixing bowl containing roller blades. The blends were mixed at 150 rpm at 350° C. for 10 minutes to disperse the components. The mixtures were then removed from the bowl and subsequently pressed into plaques at 350° C. that were ˜100 mm×100 mm by ˜0.20 mm thickness for use in electrical testing and subsequent lamination. Electrical properties of the pressed films, including Dk and Df at 10 Ghz, were tested and found to have the electrical properties shown in Table 18:

TABLE 18
Electrical properties @10 GHz of molded
PFA films having varying ratios of PFA2 to PFA1.

| | wt. % | wt. % | wt. % | Dk | Df |
|---|---|---|---|---|---|
| Loading | PFA2 | PFA1 | TiO2 | Avg/Std Dev | Avg/Std Dev |
| 100% PFA2 | 97.50% | 0.00% | 2.50% | 2.089 | 9.52E−04 |
| Polymer Basis | 100% | 0% | | 0.025 | 2.62E−05 |
| 75% PFA2 | 73.13% | 24.38% | 2.50% | 2.075 | 7.72E−04 |
| Polymer Basis | 75% | 25% | | 0.025 | 8.59E−06 |
| 50% PFA2 | 48.75% | 48.75% | 2.50% | 2.102 | 5.80E−04 |
| Polymer Basis | 50% | 50% | | 0.026 | 1.79E−05 |
| 25% PFA2 | 24.38% | 73.13% | 2.50% | 2.106 | 4.32E−04 |
| Polymer Basis | 25% | 75% | | 0.027 | 9.18E−06 |
| 15% PFA2 | 14.63% | 82.88% | 2.50% | 2.080 | 3.49E−04 |
| Polymer Basis | 15% | 85% | | 0.041 | 1.5E−05 |
| 10% PFA2 | 9.75% | 87.75% | 2.50% | 2.104 | 3.11E−04 |
| Polymer Basis | 10% | 90% | | 0.066 | 1.46E−05 |
| 5% PFA2 | 4.88% | 92.63% | 2.50% | 2.079 | 2.85E−40 |
| Polymer Basis | 5% | 95% | | 0.049 | 1.76E−05 |
| 0% PFA2 | 0.00% | 97.50% | 2.50% | 2.111 | 2.55E−04 |
| Polymer Basis | 0% | 100% | | 0.045 | 9.88E−06 |

As expected, the dielectric constant (Dk) remained fairly consistent with PFA2 loading and the dissipation factor (Df) rose in a linear fashion with increasing concentration of the PFA2 in the blend.

Measurements were also made to determine the total number of carboxyl end groups per 10⁶ carbon atoms for select blends and the results are shown in Table 19.

TABLE 19
Carboxyl end group concentration of PFA films
having varying ratios of PFA2 to PFA1.

| | wt. % | wt. % | wt. % | |
|---|---|---|---|---|
| Loading | PFA2 | PFA1 | TiO2 | Carboxyl end groups |
| 100% PFA2 | 97.50% | 0.00% | 2.50% | 214 |
| Polymer Basis | 100% | 0% | | |
| 75% PFA2 | 73.13% | 24.38% | 2.50% | 178 |
| Polymer Basis | 75% | 25% | | |
| 50% PFA2 | 48.75% | 48.75% | 2.50% | 95 |
| Polymer Basis | 50% | 50% | | |
| 25% PFA2 | 24.38% | 73.13% | 2.50% | 53 |
| Polymer Basis | 25% | 75% | | |
| 0% PFA2 | 0.00% | 97.50% | 2.50% | 7 |
| Polymer Basis | 0% | 100% | | |

As was observed with the dissipation factor data, the number of carboxyl end groups per 10⁶ carbon atoms increased in a generally linear fashion with increasing concentration of PFA2 in the PFA blend.

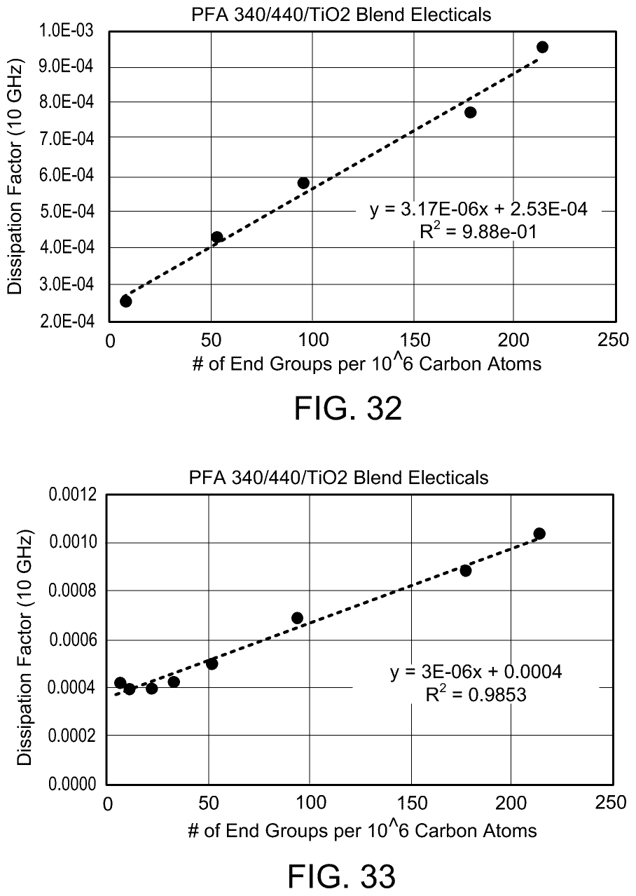

FIG. 32 is a plot of the measured dissipation factor (Df) as function of the number of carboxyl end groups per 10⁶ carbon atoms. As illustrated in this figure, the level of carboxyl end groups in the blended PFA films has a direct bearing on the electrical properties of the films.

These blended PFA films were combined with 2116C-04 quartz fabric (Shin-Etsu) and 12 μm BHFX-P92C-HG copper foil (JX Nippon Mining & Metals Corporation). Copper foil and quartz fabric were both provided as 12″×12″ panels and PFA films were provided as 4″×4″ panels. The constituent materials were laminated at 320° C. and 600 psi in an electrically heated press (PHI, City of Industry, CA) for a dwell time of 60 minutes to form copper clad laminates. The experimental details are shown in Tables 20A and 20B.

TABLE 20A
Experimental details.

| | | | Film | # End |
|---|---|---|---|---|
| Run ID | Construction | PFA film | MFR | groups |
| G2-68-1 | 12/183/2116/183/12 | 100% PFA2 | 14.0 | 214.0 |
| G2-68-2 | 12/191/2116/191/12 | 75% PFA2/25% PFA1 | 14.0 | 178.3 |
| G2-68-3 | 12/215/2116/215/12 | 50% PFA2/50% PFA1 | 14.0 | 95.0 |
| G2-68-4 | 12/233/2116/233/12 | 25% PFA2/75% PFA1 | 14.0 | 52.6 |
| G2-68-5 | 12/234/2116/234/12 | 15% PFA2/85% PFA1 | 14.0 | 33.6 |
| G2-68-6 | 12/192/2116/192/12 | 10% PFA2/90% PFA1 | 14.0 | 22.8 |
| G2-68-7 | 12/219/2116/219/12 | 5% PFA2/95% PFA1 | 14.0 | 12.0 |
| G2-68-8 | 12/218/2116/218/12 | 100% PFA1 | 14.0 | 6.6 |

TABLE 20B
Experimental details.

| | Film Zero | | | Glass | Total | Film | Theoretical |
|---|---|---|---|---|---|---|---|
| | Shear | Glass | Glass | Basis | film | Basis | Resin |
| | Viscosity, | Modulus, | CTE, | Weight, | thickness, | Weight, | Content, |
| Run ID | Pa-s | GPa | ppm/C. | g/m² | μm | g/m² | % |
| G2-68-1 | ~5000 | 78 | 0.5 | 85.5 | 366.0 | 7905.6 | 97.9% |
| G2-68-2 | ~5000 | 78 | 0.5 | 85.5 | 382.0 | 8251.2 | 97.9% |
| G2-68-3 | ~5000 | 78 | 0.5 | 85.5 | 430.0 | 9288.0 | 98.2% |
| G2-68-4 | ~5000 | 78 | 0.5 | 85.5 | 466.0 | 10065.6 | 98.3% |
| G2-68-5 | ~5000 | 78 | 0.5 | 85.5 | 468.0 | 10108.8 | 98.3% |
| G2-68-6 | ~5000 | 78 | 0.5 | 85.5 | 384.0 | 8294.4 | 98.0% |
| G2-68-7 | ~5000 | 78 | 0.5 | 85.5 | 438.0 | 9460.8 | 98.2% |
| G2-68-8 | ~5000 | 78 | 0.5 | 85.5 | 436.0 | 9417.6 | 98.2% |

The laminated materials were tested for various properties. The results are shown in Tables 21A and 21B. An etched visual inspection is a qualitative characterization of the ability of the sample to lie flat and smooth on a surface.

TABLE 21A
Experimental test results for PFA2/PFA1 blending study.

| | DK @ | DF @ |
|---|---|---|
| Run ID | 10 GHz | 10 GHz |
| G2-68-1 | 2.38 | 0.00103 |
| G2-68-2 | 2.31 | 0.00088 |
| G2-68-3 | 2.20 | 0.00069 |
| G2-68-4 | 2.17 | 0.00051 |
| G2-68-5 | 2.16 | 0.00043 |
| G2-68-6 | 2.17 | 0.00040 |
| G2-68-7 | 2.18 | 0.00040 |
| G2-68-8 | 2.19 | 0.00042 |

TABLE 21B
Experimental test results for PFA2/PFA1 blending study.

| | | | Thickness | | | Etched | |
|---|---|---|---|---|---|---|---|
| | | Average D/E | reduction | | | visual | |
| | MD Peel | Thickness | due to | | Sharpie | inspection | Estimated |
| | Strength, | (etched), | squeeze | Solder Float | wicking, | (1 = bad, | squeeze-out, |
| Run ID | pli | μm | out, % | (288 C./60 s) | mm | 5 = good) | inches |
| G2-68-1 | 3.3 | 260.0 | 29.0% | Pass | 0.72 | 1.0 | 0.81 |
| G2-68-2 | 2.2 | 346.5 | 9.3% | Pass | 0.92 | 1.0 | 0.50 |
| G2-68-3 | 1.8 | 437.0 | −1.6% | Pass | 1.53 | 5.0 | 0.38 |
| G2-68-4 | 1.9 | 468.8 | −0.6% | Pass | 2.14 | 5.0 | 0.25 |
| G2-68-5 | 1.6 | 451.5 | 3.5% | Pass | 2.04 | 5.0 | 0.25 |
| G2-68-6 | 1.7 | 411.3 | −7.1% | Pass | 2.43 | 5.0 | 0.38 |
| G2-68-7 | 1.8 | 378.5 | 13.6% | Pass | 2.69 | 1.0 | 0.50 |
| G2-68-8 | 0.5 | 260.0 | 40.4% | Pass | 2.05 | 1.0 | 0.88 |

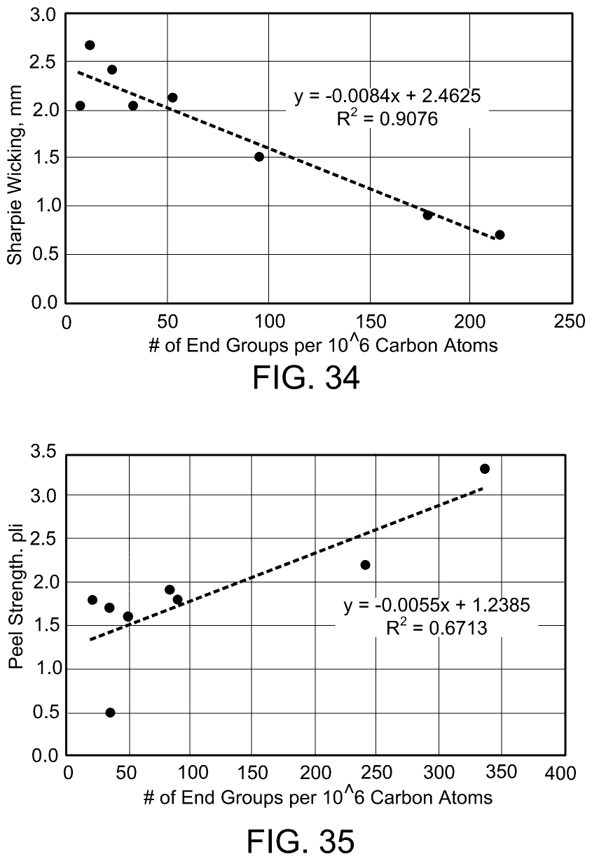

FIG. 33 is a plot of the dissipation factor of the laminate as a function of total number of carboxyl end groups per 10⁶ carbon atoms, showing a good correlation between dissipation factor and number of end groups. FIG. 34 is a plot of the sharpie wicking of the laminate as a function of total number of carboxyl end groups per 10⁶ carbon atoms, again showing good correlation between increasing carboxyl end groups and decreasing sharpie wicking. These results indicate that as the number of carboxyl end groups increases in the PFA blend, the glass bundle penetration effectiveness (as indicated by low sharpie wicking results) improves at the expense of electrical performance (dissipation factor). FIG. 35 is a plot of copper peel strength of the laminate as a function of total number of carboxyl end groups per 10⁶ carbon atoms. These data suggest a relationship between these two parameters.

### Example 11: Sharpie Wicking Behavior of Commercially Available Laminates

Sharpie wicking test results for a laminate are predictive of the laminate's performance under CAF testing. To demonstrate this association, commercially available materials known to have good CAF resistance were subjected to sharpie wicking tests. The results of these tests are shown in Table 22. These results indicate that sharpie wicking result of less than 0.5 mm corresponds to a material with good CAF resistance.

TABLE 22
Sharpie wicking results of commercially available materials.

| | | Sharpie |
|---|---|---|
| Run ID | Copper | wicking, mm |
| G2-39-1 | 5 mil RO4835T 5E/5E (Rogers Corporation, | 0.38 |
| | Chandler, AZ) | |
| G2-39-2 | 5 mil RO3003G2 TH/TH (Rogers) | 0.46 |
| G2-39-3 | 5 mil CLTE-MW TH/TH (Rogers) | 0.39 |
| G2-39-4 | 5 mil 85N HH/HH (Arlon Electronic Materials, | 0.32 |
| | Rancho Cucamonga, CA) | |
| G2-39-5 | 5 mil R5785 WH/WH (Panasonic, Osaka, Japan) | 0.35 |
| G2-39-6 | 5 mil R5785GN WH/WH (Panasonic) | 0.41 |

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain implementations, multitasking and parallel processing may be advantageous.

1. A laminate article comprising:
a dielectric substrate comprising:
a perfluorocopolymer matrix comprising a fluorinated perfluorocopolymer and a non-fluorinated perfluorocopolymer;
a quartz fabric embedded in the perfluorocopolymer matrix; and
an additive material dispersed in the perfluorocopolymer matrix, in which the additive material is capable of absorbing ultraviolet light; and
a conductive cladding disposed on a surface of the dielectric substrate.

2. The laminate article of claim 1, in which the laminate article has a thickness of between 20 μm and 200 μm.

3. The laminate article of claim 2, in which the thickness of the laminate article is between 30 μm and 90 μm.

4. The laminate article of claim 3, in which the thickness of the laminate article is between 30 μm and 60 μm.

5. The laminate article of claim 1, in which the dielectric substrate has a dielectric constant at 10 GHz of between 2.10 and 2.50.

6. The laminate article of claim 5, in which the dielectric constant of the dielectric substrate is between 2.10 and 2.30.

7. The laminate article of claim 1, in which the dielectric substrate has a thermal coefficient of dielectric constant with a value of between −250 to +50 ppm/° C. over a temperature range of 0 to 100° C.

8. The laminate article of claim 1, in which the dielectric substrate has a dissipation factor at 10 GHz of less than 0.001.

9. The laminate article of claim 8 in which the dielectric substrate has a dissipation factor at 10 GHz of between 0.0006 and 0.001.

10. The laminate article of claim 9, in which the dissipation factor of the dielectric substrate at 10 GHz is between 0.0006 and 0.0008.

11. The laminate article of any of the preceding claims, in which the laminate article has a planar shape defining an X-Y plane, and in which a coefficient of thermal expansion of the laminate article in the X-Y plane is between 5 and 25 ppm/° C.

12. The laminate article of claim 11, in which the coefficient of thermal expansion of the laminate article in the X-Y plane is between 14 and 20 ppm/° C.

13. The laminate article of claim 11, in which the coefficient of thermal expansion of the laminate article in the X-Y plane is between 16 and 22 ppm/° C.

14. The laminate article of claim 1, in which the fluorinated perfluorocopolymer comprises a fluorinated tetrafluoroethylene/perfluoro(alkyl vinyl ether) copolymer and in which the non-fluorinated perfluorocopolymer comprises a non-fluorinated tetrafluoroethylene/perfluoro(alkyl vinyl ether) copolymer.

15. The laminate article of claim 1, in which the perfluorocopolymer matrix comprises between 50 and 90 weight percent of the fluorinated perfluorocopolymer.

16. The laminate article of claim 15, in which the perfluorocopolymer matrix comprises between 10 and 50 weight percent of the non-fluorinated perfluorocopolymer.

17. The laminate article of claim 1, in which a number of carboxyl end groups per million carbon atoms in the perfluorocopolymer matrix is sufficient for the laminate article to form no conductive anodic filaments (CAF).

18. The laminate article of claim 1, in which a number of carboxyl end groups per million carbon atoms in the perfluorocopolymer matrix provides the laminate article with a peel strength between the dielectric substrate and the conductive cladding of greater than 2 lb/inch.

19. The laminate article of claim 1, in which the number of carboxyl end groups per million carbon atoms in the perfluorocopolymer matrix is between 30 and 70.

20. The laminate article of claim 1, in which the fluorinated perfluorocopolymer has 5 or fewer carboxyl end groups per million carbon atoms.

21. The laminate article of claim 1, in which the non-fluorinated perfluorocopolymer has between 100 and 300 carboxyl end groups per million carbon atoms.

22. The laminate article of claim 1, in which the perfluorocopolymer matrix has a melt flow rate (MFR) of between 10 g/10 minutes and 30 g/10 minutes.

23. The laminate article of claim 1, in which the perfluorocopolymer matrix has a solder float resistance of at least 10 seconds at 288° C.

24. The laminate article of claim 1, in which the quartz fabric has a basis weight of less than 50 g/m².

25. The laminate article of claim 24, in which the basis weight of the quartz fabric is less than 25 g/m².

26. The laminate article of claim 1, in which the quartz fabric has a thickness between 10 μm and 30 μm.

27. The laminate article of claim 1, in which the quartz fabric includes an aminosilane or methacrylate silane surface chemistry treatment.

28. The laminate article of claim 1, in which the quartz fabric comprises a plasma-treated or corona-treated quartz fabric.

29. The laminate article of claim 1, in which the quartz fabric is impregnated with a fluoropolymer.

30. The laminate article of claim 1, in which the quartz fabric comprises a fluoropolymer coating.

31. The laminate article of claim 1, in which the quartz fabric is pretreated with a fluoropolymer treatment prior to incorporation into the laminate article.

32. The laminate article of claim 1, in which the dielectric substrate comprises between 5 and 20 volume percent of the quartz fabric and between 80 and 95 volume percent of the perfluorocopolymer matrix.

33. The laminate article of claim 1, in which a water contact angle of the quartz fabric is between 0° and 60°.

34. The laminate article of claim 1, in which the additive material comprises inorganic particles.

35. The laminate article of claim 34, in which the inorganic particles comprise particles of cerium oxide, titanium dioxide, silicon dioxide, barium titanate, calcium titanate, or zinc oxide.

36. The laminate article of claim 1, in which the additive material comprises a thermoset polymer.

37. The laminate article of claim 1, in which the additive material is present in the perfluorocopolymer matrix at a volume percent of less than 2%.

38. The laminate article of claim 1, in which the additive material is dispersed homogeneously throughout the perfluorocopolymer matrix.

39. The laminate article of claim 1, in which the conductive cladding is disposed on two opposing surfaces of the dielectric substrate.

40. The laminate article of claim 1, in which the conductive cladding comprises a copper foil.

41. The laminate article of claim 40, in which the copper foil is disposed on the surface of the dielectric substrate by a lamination process.

42. The laminate article of claim 1, in which the conductive cladding has a thickness of less than 72 μm.

43. The laminate article of claim 42, in which the thickness of the conductive cladding is between 5 μm and 18 μm.

44. The laminate article of claim 1, in which the conductive cladding has a root mean square (RMS) roughness of less than 1 μm.

45. The laminate article of claim 44, in which the RMS roughness of the conductive cladding is less than 0.5 μm.

46. (canceled)

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. (canceled)

59. (canceled)

60. (canceled)

61. (canceled)

62. (canceled)

63. (canceled)

64. (canceled)

65. (canceled)

66. (canceled)

67. (canceled)

68. (canceled)

69. (canceled)

70. (canceled)

71. (canceled)

72. (canceled)

73. (canceled)

74. (canceled)

75. (canceled)

76. (canceled)

77. (canceled)

78. (canceled)
